(19) United States
(12) Patent Application Publication
(10) Pub. No.: US 2021/0309860 A1
(43) Pub. Date: Oct. 7, 2021

(54) ANTHRAQUINONIC DERIVATIVES AND THEIR USE AS COLOURING AGENTS

(71) Applicant: PILI, RAMONVILLE-SAINT-AGNE (FR)

(72) Inventors: KEVIN COTTET, RAMONVILLE SAINT AGNE (FR); GUILLAUME BOISSONNAT, RAMONVILLE SAINT AGNE (FR)

(21) Appl. No.: 17/260,242

(22) PCT Filed: Jul. 16, 2019
(86) PCT No.: PCT/EP2019/069152

§ 371 Date: Jan. 14, 2021

(30) Foreign Application Priority Data
Jul. 17, 2018 (EP) 18305972.4

(51) Int. Cl. C09B 1/503; C09B 1/08; C09B 1/28; C09B 1/32; C09B 1/51; H01L 51/00

(52) U.S. Cl. CPC C09B 1/5035; C09B 1/08; C09B 1/28; D06P 1/20; C09B 1/512; H01L 51/0052; C09B 1/32

(57) ABSTRACT

The present invention relates to a compound of formula (I-0) or a salt thereof. The invention further relates to the use of such compound as a colouring agent. The invention also relates to a colouring composition comprising such compound.

### FIELD OF THE INVENTION

The present invention relates to the field of colouring agents. More particularly, the present invention provides anthraquinone derivatives and their use as colouring agents.

### BACKGROUND OF THE INVENTION

Colouring agents can be found in many products of everyday life such as food, textile products or cosmetics. Several families have been so far developed, in particular azo compounds, polymethines and anthraquinones.

Anthraquinones are aromatic polycyclic hydrocarbons having the following backbone of formula (A):

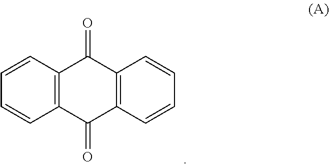 [SMILES: O=C1c2ccccc2C(=O)c2ccccc21]

Anthraquinones represent the most prevalent family of colouring agents after the azo compounds family. Based on various substitutions on the backbone of formula (A), a wide range of compounds has been prepared, thereby providing a wide diversity of colours. For instance, the anthraquinone derivative of formula (B) provides a violet dispersion in water, and the derivative of formula (C) provides a green colour. Substituents of anthraquinones are mostly nitrogen- and oxygen-based groups and are mainly inserted in positions 1 and 4.

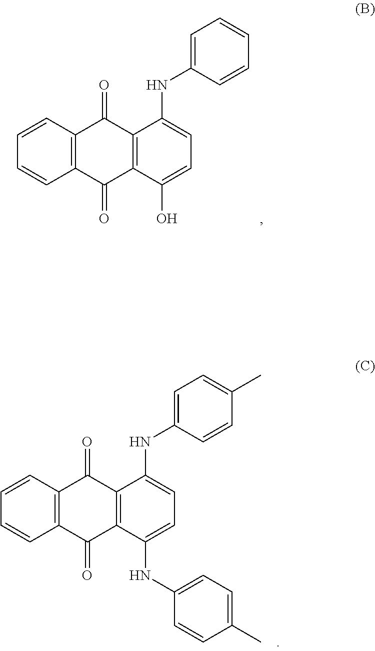 [SMILES: O=C1c2ccccc2C(=O)c2c(Nc3ccccc3)ccc(O)c21 ; Cc1ccc(Nc2ccc(Nc3ccc(C)cc3)c3c2C(=O)c2ccccc2C3=O)cc1]

A lot of anthraquinone derivatives as colouring agents have thus been developed and applied in a wide diversity of fields over the last years. However, such anthraquinone derivatives exhibit some drawbacks such as a high toxicity, and may have an insufficient tinting strength.

Therefore, there is still a need to develop further anthraquinone derivatives as efficient colouring agents.

### SUMMARY OF THE INVENTION

In this context, the inventors have developed new derivatives of anthraquinone suitable for an application in colouring compositions.

The present invention thus provides a compound or a salt thereof having the following formula (I-0):

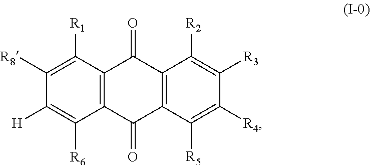

wherein
R₁, R₄, R₅, R₆ and R₈′ represent independently:
   a hydrogen atom,
   a group of the following formula (II):

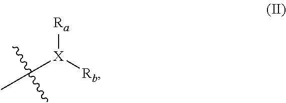

in which:
   X is a heteroatom selected from the group consisting of N and P, and
   Rₐ and R_{b} represent independently a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl and a heteroaryl,
   said aralkyl and said 3-14 membered ring are optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium,
   —SO₂—R₈, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl, and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl,
a group of formula (II′)

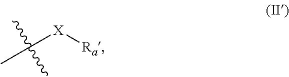

in which:
   X is a heteroatom selected from the group consisting of O, S and Se,
   Rₐ′ represents a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl, and a heteroaryl, said aralkyl and said 3-14 membered ring are optionally substituted by at least one radical selected from the group consisting of a halogen atom, —NH(CO)R₇ with R₇ being a (C₁-C₁₂)alkyl, —NO₂, —SO₃H, —CO₂H, —CN, a (C₁-C₆)alkyl optionally substituted by one halogen atom, and a tri((C₁-C₆)alkyl)ammonium, and
   —SO₂—R₈ when X is O, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl; or
a radical selected from the group consisting of
   —NO₂,
   —SO₃⁻M⁺ with M⁺ being an alkali metal cation, preferably Na⁺,
   —SO₃R₁₀ and —SO₂NR₁₁R₁₂ with R₁₀, R₁₁, R₁₂ being independently a hydrogen atom or a (C₁-C₆)alkyl;
R₂ represents:
   a (C₁-C₂₀)alkyl,
   a (C₂-C₂₀)alkenyl, or
   a (C₂-C₂₀)alkynyl,
R₃ represents
   a hydrogen atom, or
   a radical selected from the group consisting of —C(O)OR₁₃, —C(O)NR₁₄R₁₅, —C(O)SR₁₆, and —C(S)OR₁₇, with R₁₃, R₁₄, R₁₅, R₁₆ and R₁₇ being independently a hydrogen atom, a (C₁-C₁₂)alkyl, a (C₂-C₁₂)alkenyl, a (C₂-C₁₂)alkynyl, a (C₃-C₁₂)cycloalkyl, an aryl or an aralkyl;
      with the proviso that at least two of R₁, R₄, R₅, R₆ and R₈′ are not a hydrogen atom, and
      with the proviso that said compound is not
3,8-dihydroxy-1-methyl-anthracene-9,10-dione,
8-hydroxy-3-methoxy-1-methyl-anthracene-9,10-dione, and
3,8-dihydroxy-1-methyl-9,10-dioxo-anthracene-2-carboxylic acid.

In a preferred embodiment, the compound of formula (I-0) as defined above has the following formula (I):

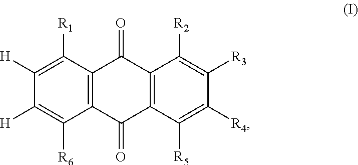

in which:
R₁, R₄, R₅ and R₆ represent independently:
   a hydrogen atom,
   a group of the following formula (II):

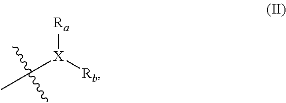

in which:
   X is a heteroatom selected from the group consisting of N and P, and
   Rₐ and R_{b} represent independently a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl and a heteroaryl,
   said aralkyl and said 3-14 membered ring are optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium,
   —SO₂—R₈, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl, and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl,
a group of formula (II′)

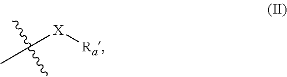

in which:
   X is a heteroatom selected from the group consisting of O, S and Se,
   Rₐ′ represents a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl, and a heteroaryl, said aralkyl and said 3-14 membered ring are optionally substituted by at least one radical selected from the group consisting of a halogen atom, —NH(CO)R₇ with R₇ being a (C₁-C₁₂)alkyl, —NO₂, —SO₃H, —CO₂H, —CN, a (C₁-C₆)alkyl optionally substituted by one halogen atom, and a tri((C₁-C₆)alkyl)ammonium, and
   —SO₂—R₈ when X is O, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl; or
a radical selected from the group consisting of
   —SO₃⁻M⁺ with M⁺ being an alkali metal cation, preferably Na⁺,
   —SO₃R₁₀ and —SO₂NR₁₁R₁₂ with R₁₀, R₁₁, R₁₂ being independently a hydrogen atom or a (C₁-C₆)alkyl;
R₂ represents:
   a (C₁-C₂₀)alkyl,
   a (C₂-C₂₀)alkenyl, or
   a (C₂-C₂₀)alkynyl,
R₃ represents
   a hydrogen atom, or
   a radical selected from the group consisting of —C(O)OR₁₃, —C(O)NR₁₄R₁₅, —C(O)SR₁₆, and —C(S)OR₁₇, with R₁₃, R₁₄, R₁₅, R₁₆ and R₁₇ being independently a hydrogen atom, a (C₁-C₁₂)alkyl, a (C₂-C₁₂)alkenyl, a (C₂-C₁₂)alkynyl, a (C₃-C₁₂)cycloalkyl, an aryl or an aralkyl;
      with the proviso that at least two of R₁, R₄, R₅ and R₆ are not a hydrogen atom, and
      with the proviso that said compound is not
3,8-dihydroxy-1-methyl-anthracene-9,10-dione,
8-hydroxy-3-methoxy-1-methyl-anthracene-9,10-dione, and
3,8-dihydroxy-1-methyl-9,10-dioxo-anthracene-2-carboxylic acid.

In a particular embodiment, R₁ represents a group of formula (II), in which:
X is N, and
Rₐ and R_{b} represent independently a hydrogen atom, a (C₁-C₆)alkyl, a cyclohexyl or a phenyl optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by at least one halogen atom, and a tri((C₁-C₆)alkyl)ammonium. In a further particular embodiment, R₁ represents a group of formula (II′), in which:
X is O, and
Rₐ′ represents a radical selected from the group consisting of a hydrogen atom and —SO₂—R₈, with R₈ being a phenyl substituted by a (C₁-C₆)alkyl.

In a particular embodiment, R₄ represents a group of formula (II), in which:
X is N, and
Rₐ and R_{b} represent independently a hydrogen atom, a (C₁-C₆) alkyl, a cyclohexyl group or a phenyl group optionally substituted by at least one radical selected from the group consisting of a halogen atom, a (C₁-C₆)alkyl optionally substituted by at least one halogen atom, —NH(CO)R₇ with R₇ being a (C₁-C₆)alkyl, —NO₂, —SO₃H, —CO₂H, and a tri(C₁-C₆ alkyl)ammonium.

In a particular embodiment, R₅ and R₆ represent independently a hydrogen atom or —NH₂, preferably a hydrogen atom.

In a particular embodiment, R₂ is a (C₁-C₆)alkyl, preferably a (C₁-C₂)alkyl, and more preferably a methyl.

In particular embodiment, R₃ is a hydrogen atom or —C(O)OR₁₃ with R₁₃ being a hydrogen atom or (C₁-C₆)alkyl, preferably a hydrogen atom.

In a preferred embodiment, the compound according to the invention is represented by formula (I) in which:
R₁ represents —OH, —O—SO₂-Tol, —NH—C₆H₅, —NH-Cy, —NHBu, or —NH—C₆H₄—NHCO—CH₃,
R₄ represents —NH—C₆H₅, —NH-Cy, —NHBu, or —NH—C₆H₄—NHCO—CH₃,
R₅ and R₆ represent independently a hydrogen atom or —NH₂, preferably a hydrogen atom,
R₃ represent a hydrogen atom or —COOH, preferably a hydrogen atom, and
R₂ is a methyl.

In a more preferred embodiment, the compound is selected from the group consisting of:
3-amino-8-hydroxy-1-methyl-anthracene-9,10-dione,
3-anilino-8-hydroxy-1-methyl-anthracene-9,10-dione,
(6-anilino-8-methyl-9,10-dioxo-1-anthryl)-4-methylbenzenesulfonate,
3,8-dianilino-1-methyl-anthracene-9,10-dione,
N-(3-((6-(3-acetamidoanilino)-8-methyl-9,10-dioxo-1-anthryl)amino)phenyl)acetamide,
3,8-bis(cyclohexylamino)-1-methyl-anthracene-9,10-dione,
3,8-bis(cyclohexylamino)-1-methyl-9,10-dioxo-9,10-dihydroanthracene-2-carboxylic acid;
3,8-bis(butylamino)-1-methyl-9,10-dioxo-9,10-dihydroanthracene-2-carboxylic acid;
1-amino-2,5-dihydroxy-4-methyl-anthracene-9,10-dione;
1,8-diamino-2,5-dihydroxy-4-methyl-anthracene-9,10-dione;
4,5-diamino-3,8-dihydroxy-1-methyl-9,10-dioxo-anthracene-2-carboxylic acid; and
4,5,7-triamino-3,8-dihydroxy-1-methyl-9,10-dioxo-anthracene-2-carboxylic acid.

A further object of the invention is a use of a compound as defined herein as a colouring agent.

Another object of the invention relates to a colouring composition comprising from 0.01% to 20%, preferably from 0.1% to 10% by weight of a compound as defined herein relative to the total weight of the composition.

In a particular embodiment, said colouring composition is a dyestuff for colouring textiles or leathers.

In a further particular embodiment, said colouring composition comprises a solvent, preferably water, and optionally (i) one or more additives facilitating the colouration of the textile or skin, preferably selected from the group consisting of antifoaming agents, anticreasing agents, wetting agents, dispersants, lubricants, detergents, inorganic salts, reducing agents, oxidising agents, carriers which cause polyester fibers to swell during dyeing and thus allow the colourants to penetrate, and antioxidants; and/or (ii) one or more additional colouring agents. In a further particular embodiment, said colouring composition is an ink or a colouring composition for colouring plastics, waxes, cellulosic materials, silicones, textiles, leathers, food compositions, cosmetic compositions, or pharmaceutical compositions.

Another object of the invention is an organic electroluminescent device or a solar cell comprising a compound as defined in the present application.

### FIGURES

FIG. 1: UV-visible spectra of compound 5 (aloesaponarin) recorded at 0.0025, 0.005, 0.01, 0.025, 0.033, 0.05, and 0.1 mg/mL.

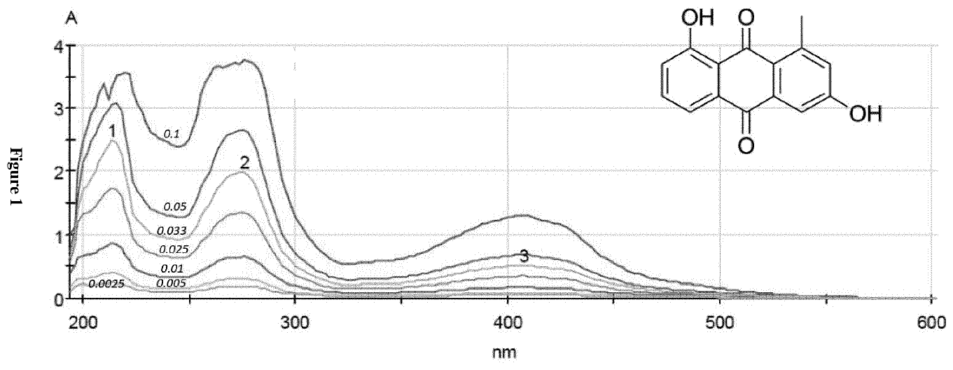

FIG. 2: UV-visible spectra of compound 6 (8-hydroxy-3-methoxy-1-methyl-anthracene-9,10-dione) recorded at 0.0025, 0.005, 0.01, 0.025, and 0.05 mg/mL.

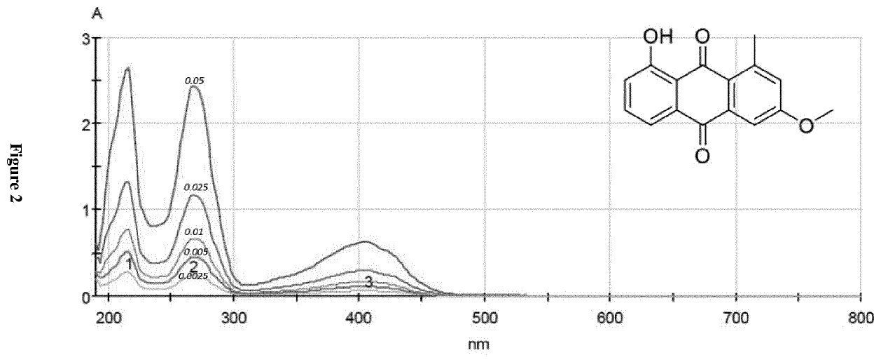

FIG. 3: UV-visible spectra of compound 8 recorded at 0.001, 0.025, 0.05, 0.1, 0.125, 0.25, 0.3, 0.5 mg/mL.

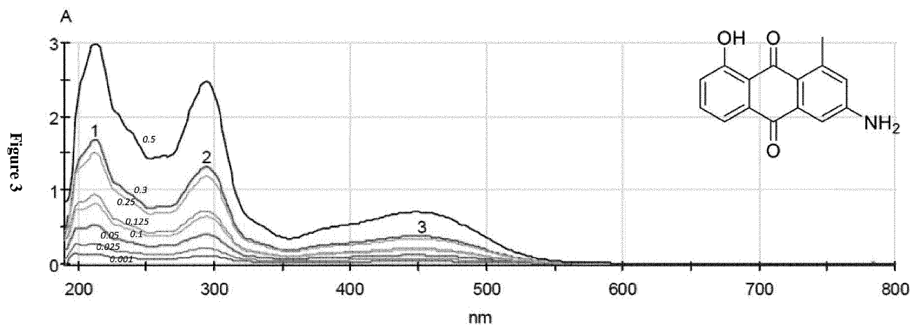

FIG. 4: UV-visible spectra of compound 9 recorded at 0.025, 0.05, 0.1, 0.25, 0.5, and 1 mg/mL.

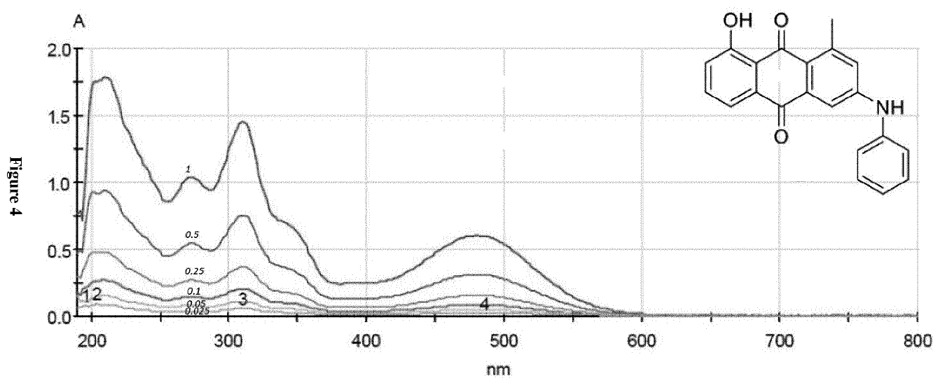

FIG. 5: UV-visible spectra of compound 10 recorded at 0.05, 0.1, 0.25, 0.5, and 1 mg/mL.

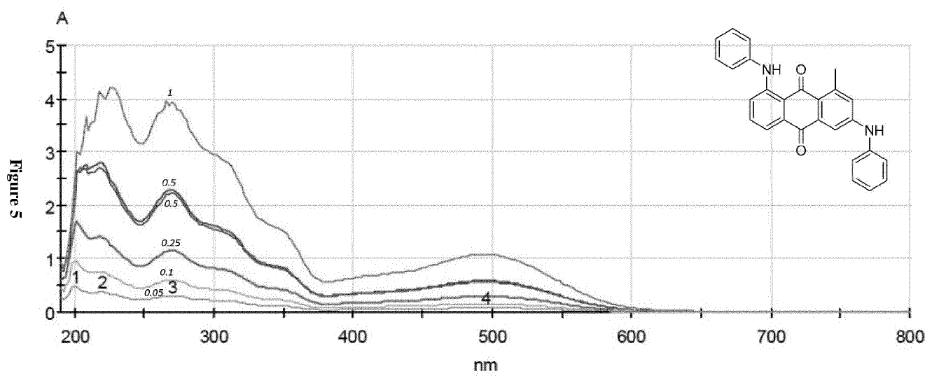

FIG. 6: UV-visible spectra of compound 11 recorded at 0.025, 0.05, 0.1, 0.25, 0.5 mg/mL.

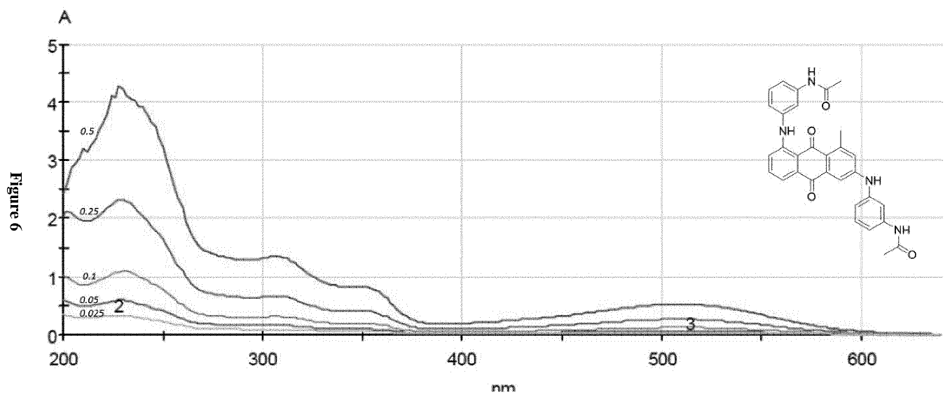

FIG. 7: UV-visible spectra of compound 12 recorded at 0.0625, 0.125, 0.25, 0.5, 1, and 2 mg/mL.

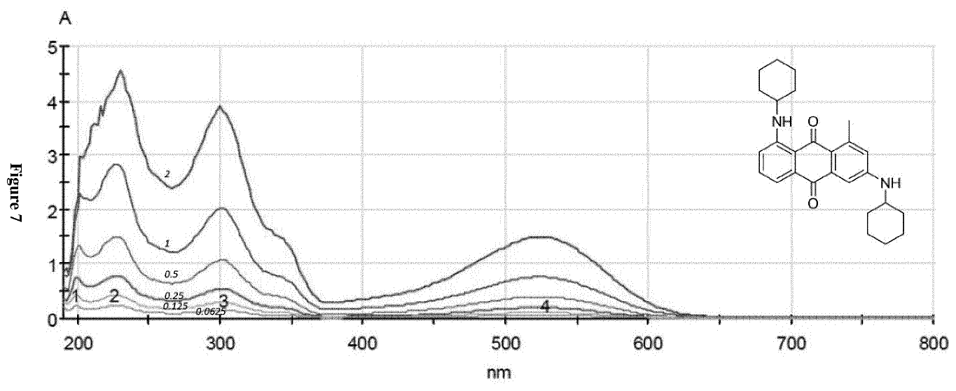

FIG. 8: UV-visible spectra of compound 14 recorded at 0.0025, 0.005, 0.01, 0.025, 0.033 and 0.04 mg/mL.

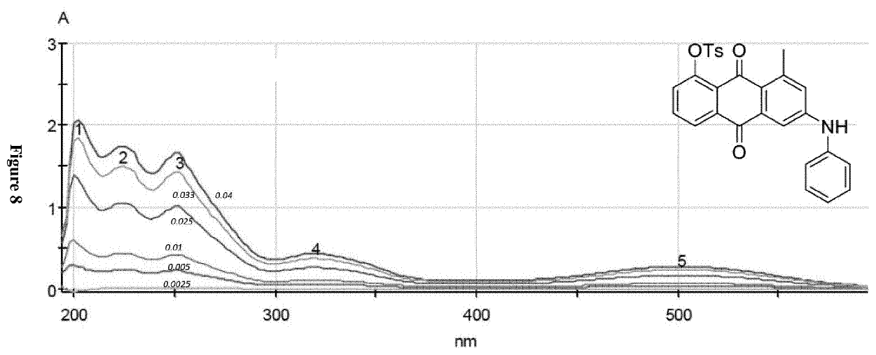

FIG. 9: UV-visible spectra of compound 18b recorded at 0.0125, 0.025, 0.05, and 0.1 mg/mL.

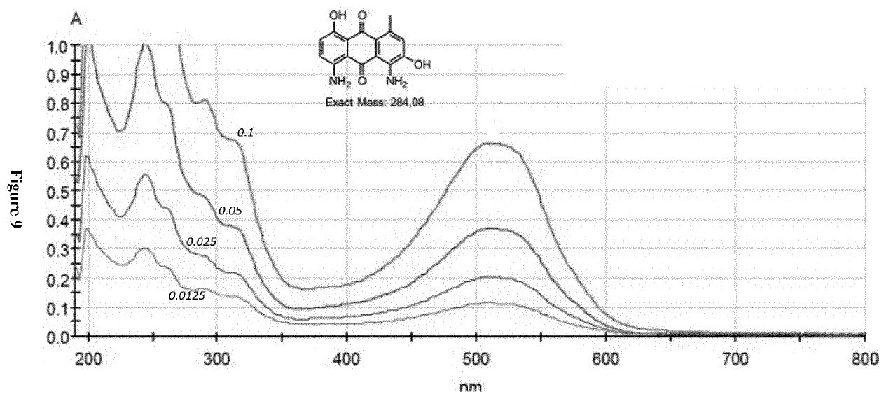

FIG. 10: UV-visible spectra of compound 19b recorded at 0.025, 0.1, 0.25, and 0.5 mg/mL.

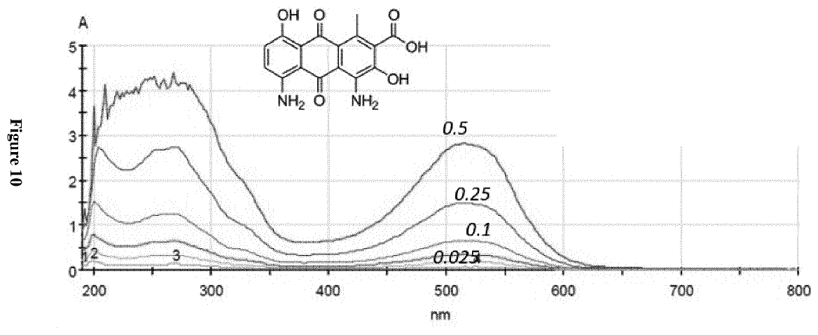

### DETAILED DESCRIPTION OF THE INVENTION

### Definitions

According to the present invention, the terms below have the following meanings:

The terms mentioned herein with prefixes such as for example C₁-C₆, C₁-C₁₂ or C₂-C₁₂ can also be used with lower numbers of carbon atoms such as C₁-C₂, C₁-C₉, or C₂-C₅. If, for example, the term C₁-C₆ is used, it means that the corresponding hydrocarbon chain may comprise from 1 to 6 carbon atoms, especially 1, 2, 3, 4, 5 or 6 carbon atoms. If, for example, the term C₂-C₅ is used, it means that the corresponding hydrocarbon chain may comprise from 2 to 5 carbon atoms, especially 2, 3, 4, or 5 carbon atoms.

The term “alkyl” refers to a saturated, linear or branched aliphatic group. The term “(C₁-C₆)alkyl” more specifically means methyl, ethyl, propyl, isopropyl, butyl, isobutyl, tert-butyl, pentyl, or hexyl. The term “(C₁-C₁₂)alkyl” more specifically means methyl, ethyl, propyl, isopropyl, butyl, isobutyl, tert-butyl, pentyl, hexyl, heptyl, octyl, nonyl, decyl, undecyl, or dodecyl. In a particular embodiment, the “alkyl” is a methyl, an ethyl, a propyl, an isopropyl, or a tert-butyl, more preferably a methyl. The term “(C₁-C₂₀)alkyl” more specifically means methyl, ethyl, propyl, isopropyl, butyl, isobutyl, tert-butyl, pentyl, hexyl, heptyl or any alkyl fatty chain having from 8 to 20 carbon atoms, such as a lauryl, myristyl, cetyl, heptadecyl, stearyl, or arachidyl chain.

The term “alkenyl” refers to an unsaturated, linear or branched aliphatic group comprising at least one carbon-carbon double bound. The term “(C₂-C₁₂)alkenyl” more specifically means ethenyl, propenyl, isopropenyl, butenyl, isobutenyl, pentenyl, hexenyl, heptenyl, octenyl, nonenyl, decenyl, undecenyl or dodecenyl. The term “(C₂-C₂₀)alkenyl” more specifically means ethenyl, propenyl, isopropenyl, butenyl, isobutenyl, pentenyl, hexenyl, heptenyl, or any alkenyl fatty or terpenic chain having from 8 to 20 carbon atoms such as oleyl, geranyl or palmitoleyl.

The term “alkynyl” refers to an unsaturated, linear or branched aliphatic group comprising at least one carbon-carbon triple bound. The term “(C₂-C₁₂)alkynyl” more specifically means ethynyl, propargyl, butynyl, pentynyl, hexynyl, heptynyl, octynyl, nonynyl, decynyl, undecynyl or dodecynyl. The term “(C₂-C₂₀)alkynyl” more specifically means ethynyl, propynyl, butynyl, pentynyl, hexynyl, heptynyl, or any alkynyl fatty chain having from 8 to 20 carbon atoms such as an octadecynyl chain.

The term “cycloalkyl” corresponds to a saturated or unsaturated mono-, bi- or tri-cyclic alkyl group comprising between 3 and 14 carbon atoms. It also includes fused, bridged, or spiro-connected cycloalkyl groups. The term “cycloalkyl” includes for instance cyclopropyl, cyclobutyl, cyclopentyl, and cyclohexyl. The term “cycloalkyl” may also refer to a 5-10 membered bridged carbocyclyl such as bicyclo[2,2,1]heptanyl, bicyclo[2,2,2]octanyl, or adamantyl, preferably bicyclo[2,2,1]heptanyl. In a preferred embodiment, the “cycloalkyl” is a cyclopropyl, cyclobutyl, cyclopentyl or a cyclohexyl.

The term “heterocycloalkyl” corresponds to a saturated or unsaturated cycloalkyl group as above defined further comprising at least one heteroatom such as nitrogen, oxygen, or sulphur atom. It also includes fused, bridged, or spiro-connected heterocycloalkyl groups. Representative heterocycloalkyl groups include, but are not limited to 3-dioxo lane, benzo [1,3] dioxolyl, azetidinyl, oxetanyl, pyrazolinyl, pyranyl, thiomorpholinyl, pyrazolidinyl, piperidyl, piperazinyl, 1,4-dioxanyl, imidazolinyl, pyrrolinyl, pyrrolidinyl, piperidinyl, imidazolidinyl, morpholinyl, 1,4-dithianyl, pyrrolidinyl, oxozolinyl, oxazolidinyl, isoxazolinyl, isoxazolidinyl, thiazolinyl, thiazolidinyl, isothiazolinyl, isothiazolidinyl, dihydropyranyl, tetrahydropyranyl, tetrahydrofuranyl, and tetrahydrothiophenyl. The term “heterocycloalkyl” may also refer to a 5-10 membered bridged heterocyclyl such as 7-oxabicyclo[2,2,1]heptanyl. In a particular embodiment, it may also refer to spiro-connected heterocycloalkyl groups or spiroheterocycloalkyl groups such as for instance oxetanyl spiro-connected with azetidinyl or piperidinyl.

The term “aryl” corresponds to a mono- or bi-cyclic aromatic hydrocarbon having from 6 to 14 carbon atoms. For instance, the term “aryl” includes phenyl, biphenyl, or naphthyl. In a preferred embodiment, the aryl is a phenyl.

The term “heteroaryl” as used herein corresponds to an aromatic, mono- or poly-cyclic group comprising between 5 and 14 atoms and comprising at least one heteroatom such as nitrogen, oxygen or sulphur atom. Examples of such mono- and poly-cyclic heteroaryl group may be: pyridinyl, thiazolyl, thiophenyl, furanyl, pyrrolyl, pyrazolyl, imidazolyl, triazolyl, tetrazolyl, benzofuranyl, thianaphthalenyl, indolyl, indolinyl, quinolinyl, isoquinolinyl, benzimidazolyl, tetrahydroquinolinyl, tetrahydroisoquinolinyl, triazinyl, thianthrenyl, isobenzofuranyl, chromenyl, xanthenyl, phenoxanthinyl, isothiazolyl, isoxazolyl, pyrazinyl, pyridazinyl, indolizinyl, isoindolyl, indazolyl, purinyl, quinolizinyl, phtalazinyl, naphthyridinyl, quinoxalinyl, quinazolinyl, cinnolinyl, pteridinyl, carbazolyl, β-carbolinyl, phenanthridinyl, acridinyl, pyrimidinyl, phenanthrolinyl, phenazinyl, phenothiazinyl, furazanyl, phenoxazinyl, isochromanyl, chromanyl, imidazolidinyl, imidazolinyl, pyrazolidinyl, pyrazolinyl, indolinyl, isoindolinyl, oxazolidinyl, benzotriazolyl, benzoisoxazolyl, oxindolyl, benzoxazolinyl, benzothienyl, benzothiazolyl, isatinyl, dihydropyridyl, pyrimidinyl, s-triazinyl, oxazolyl, or thiofuranyl.

The term “aralkyl” corresponds to an alkyl group as defined above, substituted by one aryl group as defined above. In a preferred embodiment, aralkyl is a benzyl group.

The term “halogen” corresponds to a fluorine, chlorine, bromine, or iodine atom, preferably a fluorine, chlorine or bromine.

The term “alkali metal cation” corresponds to a lithium, sodium, potassium or cesium cation, preferably a sodium cation.

The term “tri((C₁-C₆)alkyl)ammonium” corresponds a radical ammonium —NR₃⁺ wherein R is a (C₁-C₆)alkyl group. Examples of tri((C₁-C₆)alkyl)ammonium include, for instance, trimethylammonium or tributylammonium. The counterion of said tri((C₁-C₆)alkyl)ammonium is an anion such as a chloride, bromide, tetrafluoroborate, hexafluorophosphate, acetate, trifluoroacetate or tosylate anion.

The expression “substituted by at least one” means that the radical is substituted by one or several groups of the list.

Salts of compounds of formula (I-0) or (I) include without limitation alkali metal salts, alkaline-earth metal salts, ammonium salts, organic, and inorganic acid salts. As an example of alkali metal salts, sodium and potassium may be cited. As an example of alkaline-earth metal salts, calcium and magnesium salts may be cited. As an example of ammonium salts quaternary ammonium, salts such as tetramethylammonium or tetraethylammonium, and addition salts with ammonia or organic amines, such as methylamine, dimethylamine, trimethylamine, ethylamine, triethylamine, ethanolamine or tris(2-hydroxyethyl)amine may be cited. As an example of an inorganic acid salt, hydrochloric acid salt, hydrobromic acid salt, sulfuric acid salt, nitric acid salt, and phosphoric acid salt. As an example of an organic acid salt, carboxylic acid salt such as formic acid salt, acetic acid salt, trichloroacetic acid salt, propionic acid salt, oxalic acid salt, citric acid salt, lactic acid salt, malic acid salt, succinic acid salt, malonic acid salt, benzoic acid salt, maleic acid salt, fumaric acid salt, and tartaric acid salt, and sulfonic acid salts such as methanesulfonic acid salt, benzenesulfonic acid salt, and p-toluenesulfonic acid salt may be cited.

### Compounds

A compound according to the invention, or a salt thereof, has the following formula (I-0):

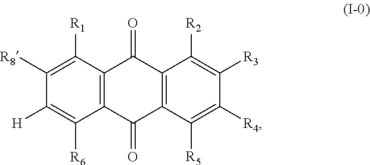

wherein:
R₁, R₄, R₅, R₆ and R₈′ represent independently:
   a hydrogen atom,
   a group of the following formula (II):

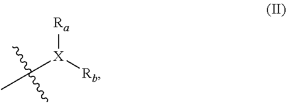

in which:
   X is a heteroatom selected from the group consisting of N and P, and
   Rₐ and R_{b} represent independently a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl and a heteroaryl,
   said aralkyl and said 3-14 membered ring are optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium,
   —SO₂—R₈, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl, and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl,
a group of formula (II′)

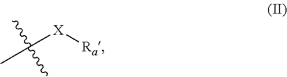

in which:
   X is a heteroatom selected from the group consisting of 0, S and Se,
   Rₐ′ represents a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl, and a heteroaryl, said aralkyl and said 3-14 membered ring are optionally substituted by at least one radical selected from the group consisting of a halogen atom, —NH(CO)R₇ with R₇ being a (C₁-C₁₂)alkyl, —NO₂, —SO₃H, —CO₂H, —CN, a (C₁-C₆)alkyl optionally substituted by one halogen atom, and a tri((C₁-C₆)alkyl)ammonium, and
   —SO₂—R₈ when X is O, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl; or
a radical selected from the group consisting of
   —NO₂,
   —SO₃⁻M⁺ with M⁺ being an alkali metal cation, preferably Na⁺,
   —SO₃R₁₀ and —SO₂NR₁₁R₁₂ with R₁₀, R₁₁, R₁₂ being independently a hydrogen atom or a (C₁-C₆)alkyl;
R₂ represents:
   a (C₁-C₂₀)alkyl,
   a (C₂-C₂₀)alkenyl, or
   a (C₂-C₂₀)alkynyl,
R₃ represents
   a hydrogen atom, or
   a radical selected from the group consisting of —C(O)OR₁₃, —C(O)NR₁₄R₁₅, —C(O)SR16, and —C(S)OR₁₇, with R₁₃, R₁₄, R₁₅, R₁₆ and R₁₇ being independently a hydrogen atom, a (C₁-C₁₂)alkyl, a (C₂-C₁₂)alkenyl, a (C₂-C₁₂)alkynyl, a (C₃-C₁₂)cycloalkyl, an aryl or an aralkyl;
      with the proviso that at least two of R₁, R₄, R₅, R₆ and R₈′ are not a hydrogen atom, and
      with the proviso that said compound is not
3,8-dihydroxy-1-methyl-anthracene-9,10-dione,
8-hydroxy-3-methoxy-1-methyl-anthracene-9,10-dione, and
3,8-dihydroxy-1-methyl-9,10-dioxo-anthracene-2-carboxylic acid.

In a particular embodiment, R₈′ is a hydrogen atom, or a group of formula (II) in which X is N and Rₐ and R_{b} are hydrogen atoms (i.e. a —NH₂ group). Preferably, R₈′ is a hydrogen atom.

In a particular embodiment, said compound of formula (I-0) has the following formula (I):

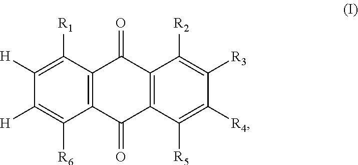

in which:
R₁, R₄, R₅ and R₆ represent independently:
   a hydrogen atom,
   a group of the following formula (II):

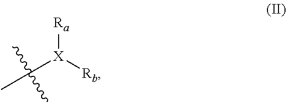

in which:
   X is a heteroatom selected from the group consisting of N and P, preferably X is N, and
   Rₐ and R_{b} represent independently a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl and a heteroaryl,
   said aralkyl and said 3-14 membered ring are optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium,
   —SO₂—R₈, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl, and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl,
a group of formula (II′)

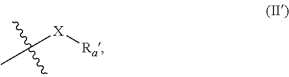

in which:
   X is a heteroatom selected from the group consisting of O, S and Se, preferably O and S, more preferably X is O,
   Rₐ′ represents a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl, and a heteroaryl, said aralkyl and said 3-14 membered ring are optionally substituted by at least one radical selected from the group consisting of a halogen atom, —NH(CO)R₇ with R₇ being a (C₁-C₁₂)alkyl, —NO₂, —SO₃H, —CO₂H, —CN, a (C₁-C₆)alkyl optionally substituted by one halogen atom, and a tri((C₁-C₆)alkyl)ammonium, and
   —SO₂—R₈ when X is O, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl; or
a radical selected from the group consisting of
   —SO₃⁻M⁺ with M⁺ being an alkali metal cation, preferably Na⁺,
   —SO₃R₁₀ and —SO₂NR₁₁R₁₂ with R₁₀, R₁₁, R₁₂ being independently a hydrogen atom or a (C₁-C₆)alkyl;
R₂ represents:
   a (C₁-C₂₀)alkyl,
   a (C₂-C₂₀)alkenyl, or
   a (C₂-C₂₀)alkynyl,
R₃ represents
   a hydrogen atom, or
   a radical selected from the group consisting of —C(O)OR₁₃, —C(O)NR₁₄R₁₅, —C(O)SR₁₆, and —C(S)OR₁₇, with R₁₃, R₁₄, R₁₅, R₁₆ and R₁₇ being independently a hydrogen atom, a (C₁-C₁₂)alkyl, a (C₂-C₁₂)alkenyl, a (C₂-C₁₂)alkynyl, a (C₃-C₁₂)cycloalkyl, an aryl or an aralkyl;
      with the proviso that at least two of R₁, R₄, R₅ and R₆ are not a hydrogen atom, and
      with the proviso that said compound is not
3,8-dihydroxy-1-methyl-anthracene-9,10-dione (also called “aloesaponarin”);
8-hydroxy-3-methoxy-1-methyl-anthracene-9,10-dione, and
3,8-dihydroxy-1-methyl-9,10-dioxo-anthracene-2-carboxylic acid.

In a particular embodiment, R₁ represents a group of the following formula (II):

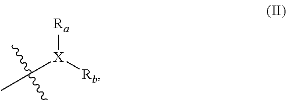

in which:
X is N, and
Rₐ and R_{b} represent independently a radical selected from the group consisting of:
   a hydrogen atom,
   a (C₁-C₆)alkyl, and
   a 3-14 membered ring selected in the group consisting of a cycloalkyl, preferably a cyclohexyl, and an aryl, preferably a phenyl,
   said 3-14 membered ring is optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium, preferably NH(CO)R₇ with R₇ being a (C₁-C₆)alkyl, more preferably NH(CO)R₇ with R₇ being a methyl.

In another particular embodiment, R₁ represents a group of formula (II), in which:
X is N, and
Rₐ and R_{b} represent independently a hydrogen atom, a (C₁-C₆)alkyl, a cyclohexyl or a phenyl optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by at least one halogen atom, and a tri((C₁-C₆)alkyl)ammonium.

In a preferred embodiment, R₁ represents a group of formula (II), in which:
X is N, and
Rₐ and R_{b} represent independently a hydrogen atom, a butyl, a cyclohexyl or a phenyl optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by at least one halogen atom, and a tri((C₁-C₆)alkyl)ammonium, preferably NH(CO)R₇ with R₇ being a (C₁-C₆)alkyl, more preferably NH(CO)R₇ with R₇ being a methyl.

In a further particular embodiment, R₁ represents a group of formula (II′)

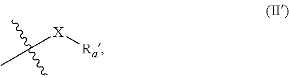

in which:
X is O, and
Rₐ′ represents a radical selected from the group consisting of:
   hydrogen atom, and
   —SO₂—R₈ with R₈ being an aryl, preferably a phenyl, said aryl is optionally substituted by at least one (C₁-C₆)alkyl, preferably a methyl.

In a preferred embodiment, R₁ represents a group of formula (II′), in which:
X is O, and
Rₐ′ represents a radical selected from the group consisting of a hydrogen atom and —SO₂—R₈, with R₈ being a phenyl substituted by a (C₁-C₆)alkyl, preferably a methyl.

In a more preferred embodiment, R₁ represents a O-Ts radical (O-tosyl) or a hydroxy group.

In a particular embodiment, R₄ represents a group of the following formula (II):

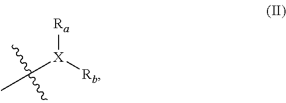

in which:
X is N, and
Rₐ and R_{b} represent independently a radical selected from the group consisting of:
   a hydrogen atom,
   a (C₁-C₆)alkyl, and
   a 3-14 membered ring selected in the group consisting of a cycloalkyl, preferably a cyclohexyl, and an aryl, preferably a phenyl,
   said 3-14 membered ring is optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium, preferably NH(CO)R₇ with R₇ being a (C₁-C₆)alkyl, more preferably NH(CO)R₇ with R₇ being a methyl.

In another particular embodiment, R₄ represents a group of formula (II), in which:
X is N, and
Rₐ and R_{b} represent independently a hydrogen atom, a (C₁-C₆) alkyl, a cyclohexyl group or a phenyl group optionally substituted by at least one radical selected from the group consisting of a halogen atom, a (C₁-C₆)alkyl optionally substituted by at least one halogen atom, —NH(CO)R₇ with R₇ being a (C₁-C₆)alkyl, —NO₂, —SO₃H, —CO₂H and a tri(C₁-C₆ alkyl)ammonium

In a preferred embodiment, R₄ represents a group of formula (II), in which:
X is N, and
Rₐ and R_{b} represent independently a hydrogen atom, a butyl, a cyclohexyl or a phenyl optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by at least one halogen atom, and a tri((C₁-C₆)alkyl)ammonium, preferably NH(CO)R₇ with R₇ being a (C₁-C₆)alkyl, more preferably NH(CO)R₇ with R₇ being a methyl.

In another particular embodiment, R₄ is a group of formula (II′) in which X is O and Rₐ′ is a hydrogen atom (i.e. a hydroxy group).

In a particular embodiment, R₅ represents a hydrogen atom, —NO₂, or a group of formula (II) in which X is N, and Rₐ and R_{b} are hydrogen atoms. In a preferred embodiment, R₅ represents a hydrogen atom or a group of formula (II) in which X is N, and Rₐ and R_{b} are hydrogen atoms (i.e. —NH₂). In a more preferred embodiment, R₅ represents a hydrogen atom.

In another particular embodiment, R₆ represents a hydrogen atom, —NO₂, or a group of formula (II) in which X is N, and Rₐ and R_{b} are hydrogen atoms (i.e. —NH₂). In a preferred embodiment, R₆ represents a hydrogen atom or a group of formula (II) in which X is N, and Rₐ and R_{b} are hydrogen atoms. In a more preferred embodiment, R₆ is a hydrogen atom.

In a preferred embodiment, R₅ and R₆ represent a hydrogen atom.

In a particular embodiment, R₂ represents a (C₁-C₂₀)alkyl or a (C₁-C₂₀)alkenyl. More particularly, R₂ may represent an alkyl fatty chain having up to 20 carbon atoms such as a lauryl, myristyl, cetyl, heptadecyl, stearyl, or arachidyl chain. R₂ may also represent an alkenyl fatty or terpenyl chain having up to 20 carbon atoms, such as an oleyl, geranyl or palmitoleyl chain. In a preferred embodiment, R₂ is a (C₁-C₆)alkyl. In a more preferred embodiment, R₂ is (C₁-C₂)alkyl (i.e. methyl or ethyl). In an even more preferred embodiment, R₂ is a methyl.

The presence of an alkyl group in position R₂, and particularly a methyl, enhances the affinity of the compounds of the invention for lipophilic materials, such as fibers, in comparison to water, Such an affinity thus enhances the adhesion of the compounds of the invention to the material and limits the possible contamination of water.

In a particular embodiment, R₃ represents a hydrogen atom or —C(O)OR₁₃ with R₁₃ being a hydrogen atom or (C₁-C₆)alkyl, preferably with R₁₃ being a hydrogen atom.

In a preferred embodiment, R₃ is a hydrogen atom.

In a preferred embodiment, a compound of the invention has the formula (I) in which:
R₁ represents
   a group of the following formula (II):

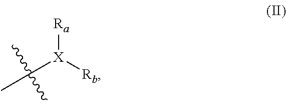

in which:
   X is N, and
   Rₐ and R_{b} are such as defined above, and preferably represent independently a radical selected from the group consisting of:
   a hydrogen atom, and
   a 3-14 membered ring selected in the group consisting of a cycloalkyl, preferably a cyclohexyl, and an aryl, preferably a phenyl, said 3-14 membered ring is optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium, preferably NH(CO)R₇ with R₇ being a (C₁-C₆)alkyl, more preferably NH(CO)R₇ with R₇ being a methyl; or
a group of formula (II′)

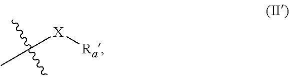

in which:
   X is O, and
   Rₐ′ is such as defined above and preferably represents a radical selected from the group consisting of:
   a hydrogen atom, and
   —SO₂—R₈ when X is O, with R₈ being an aryl, preferably a phenyl, said aryl is optionally substituted by at least one (C₁-C₆)alkyl, preferably a methyl;
R₄ represents a group of the following formula (II):

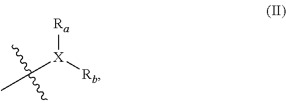

in which:
   X is N, and
   Rₐ and R_{b} are such as defined above, and preferably represent independently a radical selected from the group consisting of:
      a hydrogen atom, and
      a 3-14 membered ring selected in the group consisting of a cycloalkyl, preferably a cyclohexyl, and an aryl, preferably a phenyl, said 3-14 membered ring is optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium, preferably NH(CO)R₇ with R₇ being a (C₁-C₆)alkyl, more preferably NH(CO)R₇ with R₇ being a methyl;
R₅ and R₆ represent a hydrogen atom; and
R₂ and R₃ are such as defined above and, preferably R₂ is a methyl and R₃ is a hydrogen.

In another particular embodiment, the compound according to the invention is represented by formula (I), wherein:
R₁, R₄, R₅ and R₆ represent independently:
   a hydrogen atom,
   a group of the following formula (II):

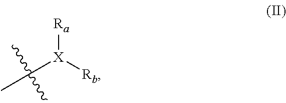

in which:
   X is a heteroatom selected from the group consisting of N and P, preferably X is N, and
   Rₐ and R_{b} represent independently a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl and a heteroaryl,
   said aralkyl and said 3-14 membered ring are optionally substituted by at least one radical —NH(CO)R₇ with R₇ being a (C₁-C₆)alkyl, preferably a methyl,
   —SO₂—R₈, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl, and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl,
a group of formula (II′)

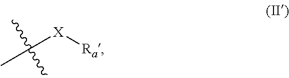

in which:
   X is a heteroatom selected from the group consisting of O, S and Se, preferably O and S, more preferably X is O,
   Rₐ′ represents a radical selected from the group consisting of:
   a hydrogen atom,
   a (C₁-C₁₂)alkyl, a (C₂-C₁₂)alkenyl, a (C₂-C₁₂)alkynyl,
   an aralkyl or a 3-14 membered ring selected in the group consisting of a cycloalkyl, an aryl, a heterocycloalkyl, and a heteroaryl, said aralkyl and said 3-14 membered ring are optionally substituted by at least one radical selected from the group consisting of a halogen atom, —NH(CO)R₇ with R₇ being a (C₁-C₁₂)alkyl, —NO₂, —SO₃H, —CO₂H, —CN, a (C₁-C₆)alkyl optionally substituted by one halogen atom, and a tri((C₁-C₆)alkyl)ammonium, and
   —SO₂—R₈ when X is O, with R₈ being an aralkyl or a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl, and
   —(CO)—R₉, with R₉ being a radical selected in the group consisting of a (C₁-C₁₂)alkyl, a (C₂-C₁₂)alkenyl, a (C₂-C₁₂)alkynyl, an aralkyl and a 3-14 membered ring selected in the group consisting of a cycloalkyl, an aryl, a heterocycloalkyl, and a heteroaryl, said aralkyl and said 3-14 membered ring are optionally substituted by at least one (C₁-C₆)alkyl; or
a radical selected from the group consisting of
   —NO₂,
   —SO₃⁻M⁺ with M⁺ being an alkali metal cation, preferably Na⁺,
   —SO₃R₁₀ and —SO₂NR₁₁R₁₂ with R₁₀, R₁₁, R₁₂ being independently a hydrogen atom or a (C₁-C₆)alkyl;
R₂ represents:
   a (C₁-C₂₀)alkyl,
   a (C₂-C₂₀)alkenyl, or
   a (C₂-C₂₀)alkynyl, preferably R₂ is a (C₁-C₂)alkyl, more preferably a methyl;
R₃ represents
   a hydrogen atom, or
   a radical selected from the group consisting of —C(O)OR₁₃, —C(O)NR₁₄R₁₅, —C(O)SR₁₆, and —C(S)OR₁₇, with R₁₃, R₁₄, R₁₅, R₁₆ and R₁₇ being independently a hydrogen atom, a (C₁-C₁₂)alkyl, a (C₂-C₁₂)alkenyl, a (C₂-C₁₂)alkynyl, a (C₃-C₁₂)cycloalkyl, an aryl or an aralkyl;
      with the proviso that at least two of R₁, R₄, R₅ and R₆ are not a hydrogen atom, and
      with the proviso that said compound is not
3,8-dihydroxy-1-methyl-anthracene-9,10-dione,
8-hydroxy-3-methoxy-1-methyl-anthracene-9,10-dione, and
3,8-dihydroxy-1-methyl-9,10-dioxo-anthracene-2-carboxylic acid.

In a particular embodiment, the compound according to the invention is represented by formula (I-0), wherein:
R₁ represents —OH, —O—SO₂-Tol, —NH—C₆H₅, —NH-Cy, —NH-Bu, or —NH—C₆H₄—NHCO—CH₃,
R₄ represents —NH—C₆H₅, —NH-Cy, —NH-Bu, or —NH—C₆H₄—NHCO—CH₃,
R₅ and R₆ represent independently a hydrogen atom, —NO₂, or —NH₂,
R₃ represents a hydrogen atom or —COOH,
R₂ is a methyl, and
R₈′ is a hydrogen atom, —NO₂ or —NH₂.

In another particular embodiment, the compound according to the invention is represented by formula (I-0), wherein:
R₁ represents —OH, —O—SO₂-Tol, —NH—C₆H₅, —NH-Cy, —NHBu, or —NH—C₆H₄—NHCO—CH₃,
R₄ represents —NH—C₆H₅, —NH-Cy, —NHBu, or —NH—C₆H₄—NHCO—CH₃,
R₅ and R₆ represent independently a hydrogen atom or —NH₂, preferably a hydrogen atom,
R₃ represent a hydrogen atom or —COOH, preferably a hydrogen atom, and
R₂ is a methyl.

In a more particular embodiment, the compound according to the invention is represented by formula (I), wherein:
R₁ represents —OH, —O—SO₂-Tol, —NH—C₆H₅, —NH-Cy, or —NH—C₆H₄—NHCO—CH₃,
R₄ represents —NH—C₆H₅, —NH-Cy, or —NH—C₆H₄—NHCO—CH₃,
R₅, R₆, and R₃ represent a hydrogen atom, and
R₂ is a methyl.

As used herein, “Tol” refers to a tolyl group, i.e. a phenyl substituted by one methyl, in ortho, meta or para position, preferably in para position. “—O—SO₂-Tol” means a toluenesulfonate group, preferably a para-toluenesulfonate. “Cy” means a cyclohexyl group. “Bu” means a butyl group.

In a preferred embodiment, the compound of the invention is selected from the group consisting of:
3-amino-8-hydroxy-1-methyl-anthracene-9,10-dione (8);
3-anilino-8-hydroxy-1-methyl-anthracene-9,10-dione (9);
3,8-dianilino-1-methyl-anthracene-9,10-dione (10);
N-(3-((6-(3-acetamidoanilino)-8-methyl-9,10-dioxo-1-anthryl)amino)phenyl)acetamide (11);
3,8-bis(cyclohexylamino)-1-methyl-anthracene-9,10-dione (12); and
(6-anilino-8-methyl-9,10-dioxo-1-anthryl)-4-methylbenzenesulfonate (14);
3,8-bis(cyclohexylamino)-1-methyl-9,10-dioxo-9,10-dihydroanthracene-2-carboxylic acid (15);
3,8-bis(butylamino)-1-methyl-9,10-dioxo-9,10-dihydroanthracene-2-carboxylic acid (16);
1-amino-2,5-dihydroxy-4-methyl-anthracene-9,10-dione (17b);
1,8-diamino-2,5-dihydroxy-4-methyl-anthracene-9,10-dione (18b);
4,5-diamino-3,8-dihydroxy-1-methyl-9,10-dioxo-anthracene-2-carboxylic acid (19b); and
4,5,7-triamino-3,8-dihydroxy-1-methyl-9,10-dioxo-anthracene-2-carboxylic acid (20b).

### Application

Another object of the present invention is the use of a compound of formula (I-0), preferably a compound of formula (I), as a colouring agent.

A “colouring agent” refers to a substance, i.e. one or more compounds of formula (I-0) or (I), which can colour a solid or a liquid substrate or a surface, when used alone or in combination with other colouring agents and/or additives. Examples of solid or liquid substrates or surfaces include, but are not limited to textile, leather, food, skin, hair, stone, glass, paper, silicone, wood, metal, plastics, and a combination thereof.

The term “textile” refers to textile fibers in any form, such as threads, fabrics or manufactured clothes. Textiles may comprise natural fibers, such as animal or plant fibers, synthetic fibers, or a combination thereof. Examples of natural plant fibers include, but are not limited to, cotton, hemp, or flax. Examples of natural animal fibers include, but are not limited to, silk or wool. Examples of synthetic fibers include, but are not limited to, modal, viscose, polyamide, polyester, or elastane.

The compound of formula (I-0) or (I) as a colouring agent may mean a “dye” or a “pigment”. As used herein, the term “dye” refers to a substance, i.e. one or more compounds of formula (I-0), which is soluble in water and can colour a solid or a liquid substrate or surface. The term “pigment” refers to a substance, i.e. one or more compounds of formula (I-0) or (I), which is not soluble in water and can colour a solid or a liquid substrate or surface when in combination with a binder.

More specifically, the compound of formula (I-0) or (I) as a colouring agent may be a vat dye, a substantive dye, a disperse dye, a direct dye, a reactive dye, a mordant dye, a metallic dye, an acid dye or a basic dye.

The compound of formula (I-0) or (I) as a colouring agent may be soluble, partially soluble or insoluble in a solvent, such as water. The colouring agent may be in the form of a pure liquid, a pure solid such as a powder, a solution, a suspension, a dispersion or an emulsion.

The compound of formula (I-0) or (I) as a colouring agent may have any colour, such as red, orange, yellow, green, blue or purple.

The compound of formula (I-0) or (I) as a colouring agent may be used in combination with one or more additional colouring agents, and optionally, with one or more additives, in particular additives facilitating the colouration of the substrate or the surface. These additional colouring agents and additives may be easily chosen by the skilled artisan depending on the applications.

In a particular embodiment, the compound of formula (I-0) or (I) as a colouring agent may be used in combination with one or more antifoaming agents, anticreasing agents, wetting agents, dispersants, lubricants, detergents, inorganic salts, reducing agents, oxidising agents, carriers which cause polyester fibers to swell during dyeing and thus allow the colourants to penetrate, and antioxidants.

The compound of formula (I-0) or (I) as a colouring agent may be used for colouring a wide diversity of substrates or surfaces, such as plastics, waxes, cellulosic materials, silicones, textiles, leathers, food compositions, cosmetic compositions, or pharmaceutical compositions.

An object of the invention is a use of a compound of formula (I-0) or (I) for preparing a colouring composition.

A further object of the invention is a colouring composition comprising a compound of formula (I-0) or (I) as defined herein.

The term “colouring composition” refers to a composition for colouring a surface or a substrate and comprising one or more compounds of formula (I-0) or (I), and optionally one or more additional colouring agents and/or one or more additives.

The colouring composition may be in the form of a liquid or a solid, such as a powder, a solution, a suspension, a dispersion or an emulsion.

A skilled person will adapt the amount of compound of formula (I-0) or (I) in the colouring composition according to the field of application and the colour intensity. In a particular embodiment, the colouring composition comprises from 0.01% to 20% by weight of a compound of formula (I-0) or (I), relative to the total weight of the composition. In a more preferred embodiment, the colouring composition comprises from 0.1% to 10% by weight of a compound of formula (I-0) or (I), relative to the total weight of the composition

The colouring composition of the invention may further comprise one or more additional colouring agents, and optionally, with one or more additives, in particular additives facilitating the colouration of the substrate or the surface. These additional colouring agents and additives may be easily chosen by the skilled artisan depending on the applications.

The colouring composition according to the invention may further comprise a solvent and optionally (i) one or more additives facilitating the colouration of the substrate, preferably the textile or skin; and/or (ii) one or more additional colouring agents. Preferably, said solvent is water. Said additives facilitating the colouration of the substrate are preferably selected from the group consisting of antifoaming agents, anticreasing agents, wetting agents, dispersants, lubricants, detergents, inorganic salts, reducing agents, oxidising agents, carriers which cause polyester fibers to swell during dyeing and thus allow the colourants to penetrate, and antioxidants.

The colouring composition of the invention may be used for colouring a wide diversity of substrates or surfaces.

An object of the invention is a use of a colouring composition as defined herein as an ink.

Another object of the invention is a use of a colouring composition as defined herein for colouring a substrate or a surface, such as plastics, waxes, cellulosic materials, silicones, textiles, leathers, food compositions, cosmetic compositions, or pharmaceutical compositions.

In a particular embodiment, the colouring composition of the invention is a colouring composition for colouring plastics, waxes, cellulosic materials, silicones, textiles, leathers, food compositions, cosmetic compositions, or pharmaceutical compositions.

The colouring composition of the invention may be a dyestuff for colouring textiles or leathers. Said “dyestuff” comprises a solvent, preferably water, one or more compounds of formula (J-O) or (I), and optionally one or more additional colouring agents and/or one or more additives.

Examples of “food” or “food compositions” include, but are not limited to, liquid compositions such as still water, sparkling water, alcoholic beverages or fruit juices, dairy products such as milk, cheese, or yoghurts, confectionary products such as chewing-gums or sweets, and food additives. Examples of “cosmetics” or “cosmetic compositions” include, but are not limited to, healthcare products such as shampoo, soap, toothpaste, or shower gel, haircare such as hair dye, gel, or hair spray, beauty products such as anti-wrinkle cream or moisturizing cream, fragrances, and make-up products such as eyeliner, lipstick, nail polish or mascara. Examples of “plastics” include, but are not limited to, polyolefins such as polyethylene or polypropylene. Examples of “cellulosic materials” include, but are not limited to, paper.

In a particular embodiment, the colouring composition of the invention is an ink. Said ink may be an ink for pen, such as a ball pen or a fountain pen, a printing ink or a screen printing ink. The formulation of said colouring composition may be easily chosen by the skilled artisan in order to get a proper viscosity and stability. In a particular embodiment, the colouring composition of the invention is an ink which comprises one or more compounds of formula (I-0), and optionally a binder such as an epoxy or polyacrylic resin, an antifoaming agent and/or a solvent such as xylene, toluene, a mineral oil, an alcohol, a ketone, water or a combination thereof.

Another object of the invention is a method for colouring a substrate or a surface (e.g. plastics, waxes, cellulosic materials, silicones, textiles, leathers, food compositions, cosmetic compositions, or pharmaceutical compositions), comprising contacting said substrate or said surface with a compound of the invention or with a colouring composition of the invention.

Another object of the invention is an organic electroluminescent device or a solar cell comprising a compound of formula (I-0) or (I).

The organic electroluminescent device may comprise an anode, a cathode, and one or more organic thin film layers which are typically disposed according to a “sandwich” structure between said anode and said cathode, wherein said one or more organic thin film layers comprise a light emitting layer and at least one of said one or more organic thin film layers comprise a compound of formula (I-0) or (I). Examples of organic thin film layers include, but are not limited to, an anode-side organic thin film layer disposed between an anode and a light emitting layer (hole transporting layer, hole injecting layer, etc.), a light emitting layer, a cathode-side organic thin film layer disposed between a cathode and a light emitting layer (electron transporting layer, electron injecting layer, etc.), a space layer, and a blocking layer. The compound of formula (I-0) or (I) may be comprised in any of the organic thin film layers of the organic electroluminescent device of the invention.

The solar cell may comprise an anode, a cathode, and one or more organic thin film layers which are typically disposed according to a “sandwich” structure between said anode and said cathode, wherein at least one of said one or more organic thin film layers comprise a compound of formula (I-0) or (I).

Said anode may be made of a metal, an alloy or any other electrically conductive material. Said anode may be made of indium oxide-tin oxide (ITO: indium tin oxide), indium oxide-tin oxide doped with silicon or silicon oxide, indium oxide-zinc oxide, indium oxide doped with tungsten oxide and zinc oxide, graphene, gold (Au), platinum (Pt), nickel (Ni), tungsten (W), chromium (Cr), molybdenum (Mo), iron (Fe), cobalt (Co), copper (Cu), palladium (Pd), titanium (Ti), a metal nitride (for example, titanium nitride), or a combination thereof.

Said cathode may be made of a metal, an alloy or any other electrically conductive material. Said cathode may be made of a metal of the group 1 or 2 of the periodic table, for example, an alkali metal, such as lithium (Li) and cesium (Cs), an alkaline earth metal, such as magnesium (Mg), an alloy containing these metals (for example, MgAg and AlLi), a rare earth metal, such as europium (Eu) and ytterbium (Yb), or an alloy containing rare earth metal(s). Alternatively, said cathode may be made of aluminum, silver, ITO, graphene, or indium oxide-tin oxide doped with silicon or silicon oxide.

Further aspects and advantages of the present invention will be described in the following examples, which should be regarded as illustrative and not limiting.

### EXAMPLES

### Example 1: Preparation of Compounds of Formula (I-0)

### Compounds 7a-c

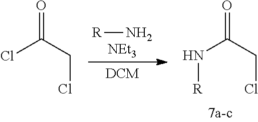

Under Argon atmosphere, amine R—NH₂ (1 eq.) and a catalytic amount of DMAP were firstly dissolved into dry dichloromethane and treated with freshly distilled triethylamine (1.1 eq.). After 10 minutes, the reaction mixture was cooled to 0° C. and freshly distilled chloroacetyl chloride (1.1 eq.) was added dropwise. The reaction mixture was then stirred overnight at room temperature. The crude was washed several times with 1M HClo_{q}), dried over sodium sulphate and evaporated to give pure product with quantitative yield.

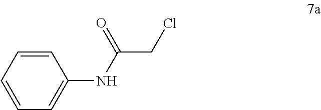 [SMILES: O=C(CCl)Nc1ccccc1]

¹H (CDCl₃) δ (ppm): 8.32 (s, 1H, (NH)), 7.48 (d, 2H, J=8 Hz), 7.27 (t, 2H, J=8 Hz), 7.09 (t, 1H, J=6 Hz), 4.12 (s, 2H).

¹³C: 164.05, 136.77, 129.13 (2×C), 125.24, 120.21 (2×C), 42.97

Yield: quantitative

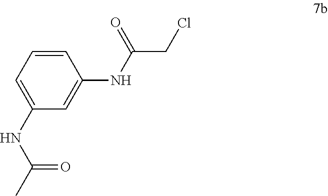

¹H (DMSO) δ (ppm): 13.35 (s, 1H), 10.00 (s, 1H), 7.92 (t, 1H, J=2H), 7.30 (t, 2H, J=8 Hz), 7.22 (t, 1H, J=8 Hz), 4.25 (s, 2H), 2.04 (s, 3H).

Yield: quantitative

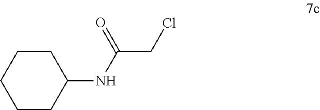 [SMILES: O=C(CCl)NC1CCCCC1]

¹H (CDCl₃) δ (ppm): 6.43 (s, 1H (NH)), 3.98 (s, 2H), 3.72 (m, 1H), 1.85 (d, 2H, 11 Hz), 1.66 (dd, 2H, J=13 Hz, J=2 Hz), 1.56 (m, 1H), 1.31 (m, 2H), 1.14 (m, 3H).

¹³C: 169.01, 165.19, 48.77, 42.69, 32.74, 25.39, 24.69 (2C)

Yield: quantitative

### Compound 8: 3-amino-8-hydroxy-1-methyl-anthracene-9,10-dione

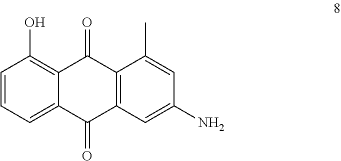 [SMILES: Cc1cc(N)cc2c1C(=O)c1c(O)cccc1C2=O]

200 mg of aloesaponarin (4.0.10⁻⁵ mol), 75 mg of chloroacetamide (9.5×10⁻⁵ mol, 2.4 eq.) 260 mg of cesium carbonate (1.9.10⁻⁴ mol, 5 eq.), and a catalytic amount of KI were heated in 30 mL of anhydrous DMF at 90° C. during 1 hour. Low conversion to alkylated derivatives was observed. The reaction mixture was heated to 140° C. overnight. Compound 8 was isolated (57 mg) with starting material and alkylated derivative (traces). Yield=27%.

¹H NMR (300 MHz, CDCl₃) δ (ppm): 7.66 (d, 1H), 7.5 (t, 1H), 7.35 (d, 1H), 7.18 (d, 1H), 6.66 (d, 1H), 4.32 (s, 1H), 2.71 (s, 1H).

¹³C NMR δ (ppm): 188.42, 166.75, 160.92, 159.48, 150.18, 142.0, 140.5, 129.4, 125.8, 123.2, 115.6, 101.0, 29.25.

GC-MS:rt=12.60 min—m/z (IE)=253.

### Compound 9: 3-anilino-8-hydroxy-1-methyl-anthracene-9,10-dione

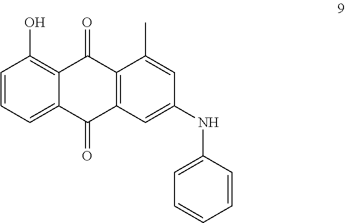 [SMILES: Cc1cc(Nc2ccccc2)cc2c1C(=O)c1c(O)cccc1C2=O]

50 mg of aloesaponarin, 66 mg of compound 7a (2 eq.), 319 mg of Cs₂CO₃ (5 eq.), a catalytic amount of KI were heated to 90° C. in 10 mL DMF for one hour. Then, the reaction mixture was heated to reflux for 16 h. Extraction (AcOEt/H₂O), and purification with flash chromatography afforded compound 9. Yield=32%.

¹H NMR (300 MHz, CDCl₃) δ (ppm): 13.21 (1H, s), 7.67 (t, J=5.2 Hz, 1H), 7.65 (d, J=0.75 Hz, 1H), 7.49 (t, J=7.7 Hz, 1H), 7.34 (t, J=7 Hz, 2H), 7.18 (t, J=7.0 Hz, 2H), 7.11 (t, J=7.7 Hz, 1H), 6.97 (d, J=0.5 Hz, 1H), 2.71 (s, 3H).

¹³C NMR δ (ppm): 184.0, 183.12, 162.92, 147.7, 139.20, 135.0, 134.4, 130.3, 129.9, 125.1, 122.9, 121.6, 118.9, 117.3, 24.5.

### Compound 10: 3,8-dianilino-1-methyl-anthracene-9,10-dione

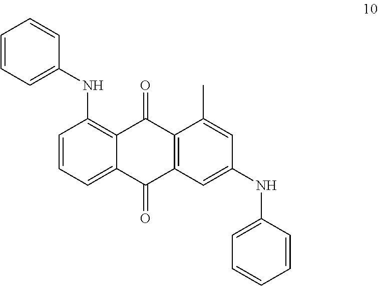 [SMILES: Cc1cc(Nc2ccccc2)cc2c1C(=O)c1c(Nc3ccccc3)cccc1C2=O]

100 mg of aloesaponarin, 120 mg of compound 7a (4 eq.), 640 mg of Cs₂CO₃ (5 eq.) and a catalytic amount of KI were heated to 90° C. in 10 mL DMF for one hour. Then, the reaction mixture was heated to reflux for 16 h. Extraction (AcOEt/H₂O), and purification with flash chromatography afforded compound 10. Yield=16%.

¹H NMR (300 MHz, CDCl₃) δ (ppm): 7.66 (d, J=2.7 Hz, 1H), 7.57 (dd J=6.7 Hz, 1 Hz, 1H), 7.46 (dd, J=6.7 Hz, 1 Hz, 1H), 7.36-7.30 (m, 5H), 7.25 (dd, J=9.4 Hz, 2 Hz), 7.17 (dd J=6.7 Hz, 1 Hz, 1H), 7.12-7.04 (m, 2.38), 7.0 (dd, J=2.6, 0.5 Hz, 1H), 2.74 (s, 3H).

¹³C δ (ppm): 187.38, 184.45 148.42, 147.45, 144.34, 140.12, 140.05, 136.44, 134.35, 134.28, 133.52, 129.69, 129.50, 129.32 124.45, 123.88, 123.77, 122.91, 121.16, 120.35, 119.83, 117.06, 111.0, 72.58, 61.72, 60.42, 29.71, 24.37.

### Compound 11: N-(3-((6-(3-acetamidoanilino)-8-methyl-9,10-dioxo-1-anthryl)amino)phenyl) Acetamide

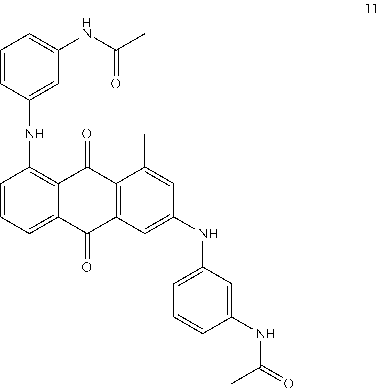 [SMILES: CC(=O)Nc1cccc(Nc2cc(C)c3c(c2)C(=O)c2cccc(Nc4cccc(NC(C)=O)c4)c2C3=O)c1]

200 mg of aloesaponarin, 890 mg of compound 7b (5 eq.), 1.20 g of Cs₂CO₃ (5 eq.) and a catalytic amount of KI were heated to 90° C. in 10 mL DMF for one hour. Then, the reaction mixture was heated to reflux for 16 h. Extraction (AcOEt/H₂O), and purification with flash chromatography afforded compound 11. Yield=64%.

¹H NMR (300 MHz, DMSO) δ (ppm): 11.34 (NH, d, J=1.5 Hz), 10.02 (2×NH, dd, J₁=6 Hz, J₂=1.5 Hz), 9.21 (NH, d, J=1.5 Hz), 7.69 (1H, s), 7.66 (2H d, J=2 Hz), 7.59 (2H, s), 7.55 (1H, m), 7.32 (2H, t, J=8.5 Hz), 7.23 (2H, t; J=6 Hz), 7.01 (1H, d, J=3.5 Hz), 6.91 (1H, d, J=3.5 Hz), 2.70 (3H, s), 2.05 (3H, s), 2.04 (3H, s).

MS: m/z=517.

### Compound 12: 3,8-bis(cyclohexylamino)-1-methyl-anthracene-9,10-dione

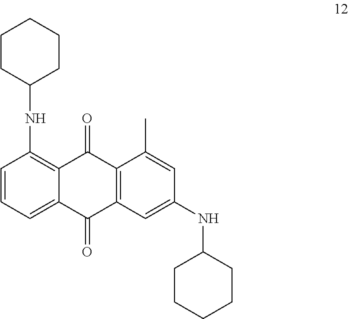 [SMILES: Cc1cc(NC2CCCCC2)cc2c1C(=O)c1c(NC3CCCCC3)cccc1C2=O]

200 mg of aloesaponarin, 688 mg of compound 7c (5 eq.), 640 mg of Cs₂CO₃ (5 eq.) and a catalytic amount of KI were heated to 90° C. in 10 mL DMF for one hour. Then, the reaction mixture was heated to reflux for 16 h. Extraction (AcOEt/H₂O), and purification with flash chromatography afforded compound 12 in 4% yield.

¹H NMR (300 MHz, CDCl₃) δ (ppm): 9.70 (1H, d, J=4 Hz), 7.38 (1H, td, J₁=7 Hz, J₂=1.5 Hz), 7.34 (1H, t, J=8 Hz), 6.96 (1H, d, J=8 Hz), 6.51 (d, 1H, J=1.5 Hz), 2.69 (3H, s), 2.06-1.90 (6H), 1.80-166 (m, 6H), 1.42-1.29 (m, 12H), 1.27-1.12 (m, 6H).

### Compound 14: (6-anilino-8-methyl-9,10-dioxo-1-anthryl)-4-methylbenzenesulfonate

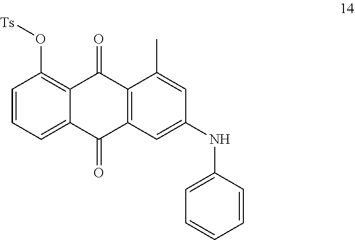 [SMILES: Cc1ccc(S(=O)(=O)Oc2cccc3c2C(=O)c2c(C)cc(Nc4ccccc4)cc2C3=O)cc1]

The preparation of the compound 14 is illustrated below.

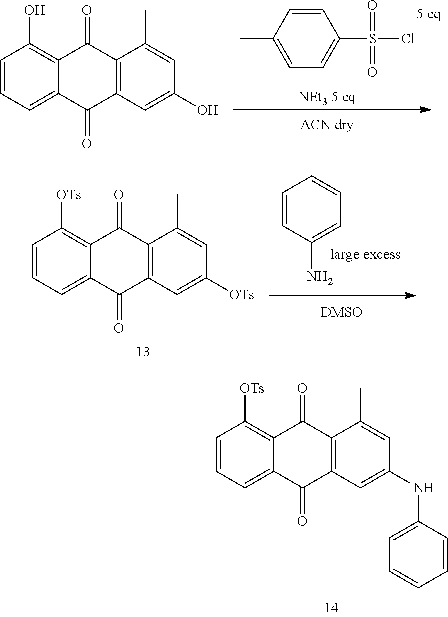 [SMILES: Cc1cc(O)cc2c1C(=O)c1c(O)cccc1C2=O ; Cc1ccc(S(=O)(=O)Cl)cc1 ; Cc1ccc(S(=O)(=O)Oc2cc(C)c3c(c2)C(=O)c2cccc(OS(=O)(=O)c4ccc(C)cc4)c2C3=O)cc1 ; Nc1ccccc1 ; Cc1ccc(S(=O)(=O)Oc2cccc3c2C(=O)c2c(C)cc(Nc4ccccc4)cc2C3=O)cc1]

0.1 g of aloesaponarin, (3.9.10⁻⁴ mol), 187 mg of tosyl chloride (9.8.10⁻⁴ mol, 2.5 eq.), 280 μL of triethylamine (2.0.10⁻³, 5 eq.) were refluxed overnight in 3 mL of acetonitrile. The solvent was removed under reduced pressure, the crude solubilized in AcOEt and washed several times with 1M HO/NaCl solution. Flash chromatography allowed the isolation of compound 13 in 55% yield.

225 mg of compound 13 (4.0.10⁻⁴ mol, 1 eq.) were heated at 120° C. overnight in 5 mL of a 1/1 DMSO/Aniline mixture. The resultant slurry was extracted with ethyl acetate and washed several times with HCl and NaCl solutions, and purified by flash chromatography to afford compound 14 in 88% yield.

¹H NMR (300 MHz, DMSO) δ (ppm): 10.99 (s, 1H), 7.79 (d, J=9 Hz, 2H) 7.57 (d, J=0.5 Hz), 7.52 (d, J=25 Hz, 1H), 7.46 (d, J=9 Hz, 2H), 7.42 (d, J=0.5 Hz, 1H), 7.38 (d, 7 Hz, 2H), 7.16 (t, J=7.8 Hz, 1H), 6.93 (t, J=11.5 Hz, 2H), 6.48 (d, 8.72 Hz, 2H), 6.41 (t J=9H, 1H).

¹³C NMR δ (ppm): 188.2 183.51, 152.81, 148.87, 147.00, 145.14, 139.70, 137.40, 135.91, 134.01, 132.11, 131.67, 130.95, 129.29, 128.80, 124.81, 123.80, 121.14, 117.95, 117.76, 116.06, 115.72, 114.27, 25.61, 24.06.

### Compound 15: 3,8-bis(cyclohexylamino)-1-methyl-9,10-dioxo-9,10-dihydroanthracene-2-carboxylic acid

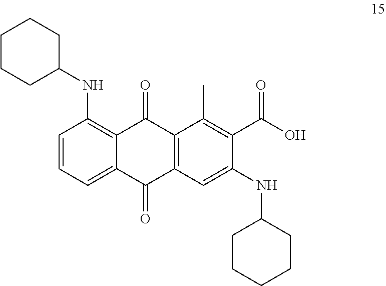 [SMILES: Cc1c(C(=O)O)c(NC2CCCCC2)cc2c1C(=O)c1c(NC3CCCCC3)cccc1C2=O]

A microwave vial was charged with compound 13 (30 mg, 0.049 mmol), cyclohexylamine (3.2 mL, 27.7 mmol, 800 equiv.) and wet DMSO (2 mL). The mixture was stirred at 100° C. for 1 h under microwaves irradiation before it was allowed to reached ambient temperature. The mixture was quenched with a 1 M HCl solution, and extracted with Et₂O. The combined organic layers were washed with a saturated solution of NaCl, dried over anhydrous MgSO₄ and concentrated in vacuo. The resulting residue was purified by flash chromatography (CycloHexane/AcOEt, 80:20 to 50/50) to give compound 15 as a red solid (13 mg, 81%).

¹H NMR (400 MHz, DMSO-d₆) δ 10.86 (s, 1H), 9.65 (d, J=7.6 Hz, 1H), 8.26 (d, J=7.9 Hz, 1H), 7.56 (dd, J=8.6, 7.3 Hz, 1H), 7.52 (s, 1H), 7.34 (dd, J=7.3, 1.0 Hz, 1H), 7.30-7.23 (m, 1H), 3.84-3.68 (m, 1H), 3.67-2.54 (m, 1H), 2.62 (s, 3H), 2.03-1.94 (m, 2H), 1.84 (m, 2H), 1.72 (m, 4H), 1.59 (m, 2H), 1.50-1.02 (m, 10H).

¹³C NMR (101 MHz, DMSO-d₆) δ 186.6, 183.3, 165.1, 157.4, 149.9, 140.1, 134.8, 134.5, 134.3, 133.5, 124.5, 119.2, 113.9, 113.2, 110.9, 49.8, 47.8, 32.4, 32.2, 25.2, 24.6, 24.1, 19.4 MS (ESI−) 459.38 (ESI+) 462.19

### Compound 16: 3,8-bis(butylamino)-1-methyl-9,10-dioxo-9,10-dihydroanthracene-2-carboxylic acid

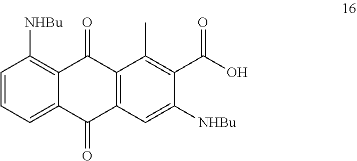

A microwave vial was charged with compound 13 (30 mg, 0.049 mmol), butylamine (3.9 mL, 39.6 mmol, 800 equiv.) and wet DMSO (2 mL). The mixture was stirred at 100° C. for 1 h under microwaves irradiation before it was allowed to reached ambient temperature. The mixture was quenched with a 1 M HCl solution, and extracted with Et₂O. The combined organic layers were washed with a saturated solution of NaCl, dried over anhydrous MgSO₄ and concentrated in vacuo. The resulting residue was purified by flash chromatography (dichloromethane/MeOH, 95:05 to 50:50) to give compound 16 as a red solid (5 mg, 25%).

¹H NMR (400 MHz, Chloroform-d) δ 10.93 (s, 1H), 9.53 (t, J=5.3 Hz, 1H), 8.33 (d, J=8.6 Hz, 1H), 7.57 (dd, J=8.6, 7.3 Hz, 1H), 7.53 (s, 1H), 7.35 (dd, J=7.4, 1.1 Hz, 1H), 7.21 (dd, J=8.8, 1.1 Hz, 1H), 3.32 (td, J=6.8, 5.7 Hz, 2H), 3.23 (td, J=6.8, 5.7 Hz, 2H), 2.61 (s, 3H), 1.65 (tt, J=7.7, 6.2 Hz, 2H), 1.54-1.31 (m, 6H), 0.93 (dt, J=19.3, 7.3 Hz, 6H).

¹³C NMR (101 MHz, Chloroform-d) δ 186.6, 183.3, 166.0, 157.5, 150.8, 140.1, 134.9, 134.6, 134.3, 133.3, 124.5, 118.6, 114.0, 113.4, 110.9, 31.0, 30.7, 19.8, 19.6, 13.7, 13.7

MS (ESIpos) 409.15

### Compound 17b: 1-amino-2,5-dihydroxy-4-methyl-anthracene-9,10-dione

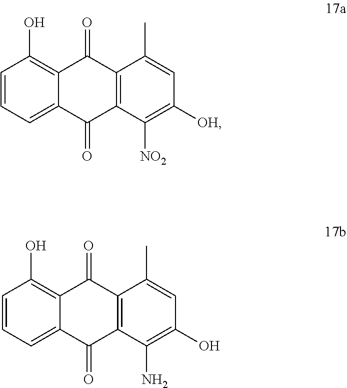 [SMILES: Cc1cc(O)c([N+](=O)[O-])c2c1C(=O)c1c(O)cccc1C2=O ; Cc1cc(O)c(N)c2c1C(=O)c1c(O)cccc1C2=O]

140 mg of aloesaponarin were partially dissolved in 6 mL di dichloroethane at 0° C. Then, 50 μL of a 60% HNO₃ solution and one drop of concentrated sulfuric acid were added dropwise. The solution was stirred over 5 hours. The reaction crude was washed several times with distillated water and brine. The organic phase was evaporated under reduced pressure to afford a crude mixture. The later can be fractioned on silica using a gradient of methanol in dichloromethane (from 1 to 15%) to obtain 31 mg of compound 17a with 21% yield.

¹H NMR (MeOD) 7.47 (d, J=2.5 Hz, 1H), 7.46 (s, 1H), 7.11 (dd J=6.9 Hz, H=2.3 Hz, 1H), 6.79 (s, 1H), 2.61 (s, 3H)

MS: (ESI−) m/z=343.39

Then, 12 mg of compound 17a were dissolved in 3 mL of water and a large excess of hydrazine monohydrate solution (0.2 mL of an 50% aqueous solution). The reaction was monitored by Thin-Layer Chromatography (TLC) and quenched with 100 mL of 1M HCl solution after 1.5 hours. Compound 17b was obtained by three successive extractions with ethyl acetate under vigorous agitation. The purple compound 17b (90% yield) can be directly use without any chromatography step.

¹H NMR (MeOD): 7.64 (dd, J=4.5 Hz, 1H), 7.52 (t, J=6.5 Hz, 1H), 7.07 (dd, J=8 Hz), 6.69 (s, 1H); 2.56 (s, 3H)

¹³C NMR (MeOD): 189.5, 184.49, 161.73, 151.18, 146.48, 142.34, 134.68, 134.57, 121.86, 119.90, 118.04, 117.16, 112.37, 23.38

MS: (ESI−) m/z=268.35

### Compound 18b: 1,8-diamino-2,5-dihydroxy-4-methyl-anthracene-9,10-dione

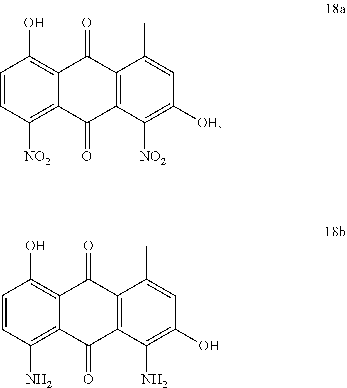 [SMILES: Cc1cc(O)c([N+](=O)[O-])c2c1C(=O)c1c(O)ccc([N+](=O)[O-])c1C2=O ; Cc1cc(O)c(N)c2c1C(=O)c1c(O)ccc(N)c1C2=O]

140 mg of Aloesaponarin were partially dissolved in 6 mL of dichloroethane at 0° C. Then, 50 uL of a 60% HNO3 solution and one drop of concentrated sulfuric acid were added dropwise. The solution was stirred over 5 hours. The reaction crude was washed several times with distillated water and brine. The organic phase was evaporated under reduced pressure to afford a crude mixture. The later can be fractioned on silica using a gradient of methanol in dichloromethane (from 1 to 15%) to obtain 18 mg of compound 18a.

¹H NMR (MeOD) 7.26 (t, 1H), 7.26 (d, 1H), 6.37 (s, 1H), 2.51 (s, 3H)

MS: (ESI−) m/z=343.39

Then, 12 mg of compound 18a were dissolved in 3 mL of water and a large excess of hydrazine monohydrate solution (0.2 mL of an 50% aqueous solution). The reaction was monitored by TLC and quenched with 100 mL of 1M HCl solution after 1.5 hours. Compound 18b was obtained by three successive extractions with ethyl acetate under vigorous agitation. The purple compound 18b (90% yield) can be directly used without any chromatography step.

¹H (MeOD): 7.71 (d, J=8.21 Hz, 1H), 7.50 (d, J=8.21 Hz, 1H), 6.85 (s, 1H), 2.61 (s, 3H)

### Compound 19b: 4,5-diamino-3,8-dihydroxy-1-methyl-9,10-dioxo-anthracene-2-carboxylic acid

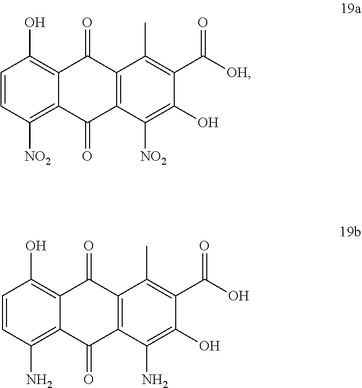 [SMILES: Cc1c(C(=O)O)c(O)c([N+](=O)[O-])c2c1C(=O)c1c(O)ccc([N+](=O)[O-])c1C2=O ; Cc1c(C(=O)O)c(O)c(N)c2c1C(=O)c1c(O)ccc(N)c1C2=O]

400 mg of 3,8-dihydroxy-1-methyl-9,10-dioxo-anthracene-2-carboxylic acid were dissolved in 8 mL of sulphuric acid and 200 μL of a 55% solution of nitric acid. After 30 min the crude was diluted in ethyl acetate and washed several times with water to remove acid traces and purified through silica gel to afford compound 19a (35% yield).

¹H NMR (MeOD): 8.04 (d, J=8.61 Hz, 1H), 7.54 (J=8.6 Hz), 2.92 (s, 3H)

Mass spectrometry: ESI (−): 387 (M−H)

Then, 18 mg of compound 19a were dissolved into 4 mL of water, then 3 drops of hydrazine solution were added to the reaction mixture. After 12 hours, a TLC monitoring showed starting material. 4 drops were added and the reaction left for 2 days. Once the reaction was over, ethyl acetate and 1M HCl were added. After several washings, the product was dryed and purified through a silica gel chromatography to afford compound 19b with 86% yield.

¹H NMR (MeOD): 7.33 (dd, J=8 Hz, 1 Hz, 1H), 6.73 (dd, J=8 Hz, 1 Hz, 1H), 2.56 (s, 3H)

Mass spectrometry: ESI (+): 351 (M+Na), 329 (M+)

### Compound 20b: 4,5,7-triamino-3,8-dihydroxy-1-methyl-9,10-dioxo-anthracene-2-carboxylic acid

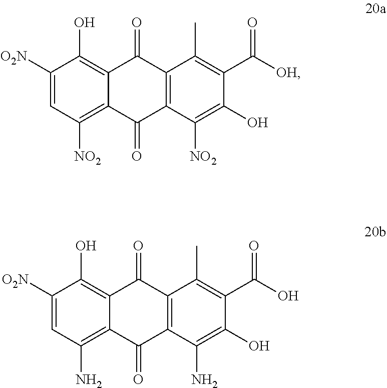 [SMILES: Cc1c(C(=O)O)c(O)c([N+](=O)[O-])c2c1C(=O)c1c(O)c([N+](=O)[O-])cc([N+](=O)[O-])c1C2=O ; Cc1c(C(=O)O)c(O)c(N)c2c1C(=O)c1c(O)c([N+](=O)[O-])cc(N)c1C2=O]

400 mg of 3,8-dihydroxy-1-methyl-9,10-dioxo-anthracene-2-carboxylic acid were dissolved in 8 mL of sulphuric acid and 200 μL of a 55% solution of nitric acid. After 30 min, the crude was diluted in ethyl acetate and washed several times with water to remove acid traces and purified through silica gel to afford compound 20a (41% yield).

¹H NMR (MeOD): 8.41 (s, 1H), 2.86 (s, 3H)

Mass spectrometry: ESI (−): 432.44

Then, 35 mg of compound 20a were dissolved in 3 mL of water and a large excess of hydrazine monohydrate solution (0.2 mL of an 50% aqueous solution). The reaction was monitored by TLC and quenched with 100 mL of 1M HCl solution after 1.5 hours. Compound 20b was obtained by three successive extractions with ethyl acetate under vigorous agitation. The purple compound 20b (90% yield) can be directly use without any chromatography step.

MS: (ESI−) m/z=432 (M-H)

### Example 2: UV-Visible Analysis

UV-Visible analysis was carried on a Genesys10 UV photometer and recorded with the help of “VisionLite Scan” software. For each molecule, a certain amount was weighed with a precision balance and fully dissolved (under sonication if necessary) in methanol to obtain a mother solution at 1 mg/mL. Serial dilutions were performed to obtain samples in a range from 0.0025 mg/mL to 0.5 mg/mL. Samples were analyzed from 190 to 800 nm in a 1 cm quartz cuvette. For each concentration, the wavelength of maximum absorption in the visible spectra (400-800 nm) was recorded with a precision of 2 nm, and the width was measured at A/2. Additionally, molar extinction coefficient ε was calculated for each sample and the log of the average value presented. λ_{max visible} characterizes the colour, L_{1/2} characterizes the brilliance of the colour, ε characterizes the strength of the colour.

TABLE 1
UV-vis characterization of compounds 8, 9, 10, 11, 12 and 14

| Compound | λ_{max visible} (nm) | L_{1/2} (nm) | log ε | Colour |
|---|---|---|---|---|
| 5 | 408 | 94 | 3.5 | Yellow |
| 6 | 406 | 81 | 3.62 | Stronger yellow |
| 7 (“DEME”)* | 408 | 86 | 3.9 | Yellow |
| 8 | 452 | 142 | 2.44 | Orange |
| 9 | 480 | 104 | 2.25 | “Carmine-like” red |
| 10 | 496 | 152 | 2.72 | Purple/red purplish |
| 11 | 510 | 128 | 2.8 | Purple |
| 12 | 524 | 94 | 2.46 | Purple |
| 14 | 508 | 104 | 3.12 | Red-purple |
| 17b | 498 | 100 | 3.41 | Purple |
| 18b | 512 | 109 | 3.33 | Purple |
| 19b | 518 | 106 | 3.25 | Purple |

*DEME = 3,8-dihydroxy-1-methyl-9,10-dioxo-anthracene-2-carboxylic acid

### Example 3: Influence of the Alkyl Group in Position R2 on the Physico-Chemical Properties of Compounds of the Invention

The partition coefficient between water and octanol (log P=log(C_{octanol}/C_{water})), and the solubility in water at a pH=4 of compounds of the invention were assessed and compared with those of the corresponding non-methylated compounds.
The partition coefficient between water and octanol is an efficient measurement of the difference of affinity of the dye between hydrophobic phases (such as a textile fiber environment) and water. When log P increases, the amount of dye needed to reach a hue is reduced and the exhaustion rate is better. This leads to a more efficient process as well as fewer residual dyes in the dyebath after dyeing.
The solubility of the corresponding molecules in water at a pH=4 (classic dying process). The lower the solubility, the less the water is contaminated by residual dyestuff.

This two parameters have been calculated using a predictive tool.

Chemicalize prediction tool: Chemicalize is a chemical properties predictive tool, from the ChemAxon Software. Results of partition coefficients and solubility predictions for compounds of the invention and the corresponding non-methylated compounds are summarized in Table 1.

TABLE 1

| Compound | 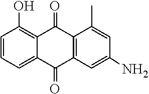 [SMILES: Cc1cc(N)cc2c1C(=O)c1c(O)cccc1C2=O] | 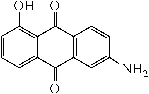 [SMILES: Nc1ccc2c(c1)C(=O)c1cccc(O)c1C2=O] | 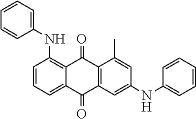 [SMILES: Cc1cc(Nc2ccccc2)cc2c1C(=O)c1c(Nc3ccccc3)cccc1C2=O] | 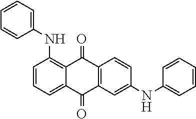 [SMILES: O=C1c2cc(Nc3ccccc3)ccc2C(=O)c2c(Nc3ccccc3)cccc21] |
|---|---|---|---|---|
| LogP | 2.93 | 2.4 | 7.6 | 7.1 |
| Solubility | 0.012 mg/mL | 0.035 mg/mL | 0 mg/mL | 0 mg/mL |
| at pH = 4 | | | | |
| Compound | 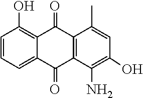 [SMILES: Cc1cc(O)c(N)c2c1C(=O)c1c(O)cccc1C2=O] | 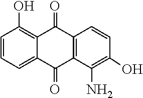 [SMILES: Nc1c(O)ccc2c1C(=O)c1cccc(O)c1C2=O] | 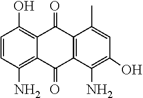 [SMILES: Cc1cc(O)c(N)c2c1C(=O)c1c(O)ccc(N)c1C2=O] | 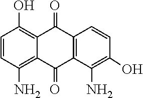 [SMILES: Nc1ccc(O)c2c1C(=O)c1c(ccc(O)c1N)C2=O] |
| LogP | 3.25 | 2.73 | 3.089 | 2.57 |
| Solubility | 0.032 mg/mL | 0.097 mg/mL | 0.055 mg/mL | 0.164 mg/mL |
| at pH = 4 | | | | |
| Compound | 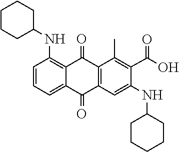 [SMILES: Cc1c(C(=O)O)c(NC2CCCCC2)cc2c1C(=O)c1c(NC3CCCCC3)cccc1C2=O] | 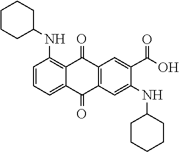 [SMILES: O=C(O)c1cc2c(cc1NC1CCCCC1)C(=O)c1cccc(NC3CCCCC3)c1C2=O] | 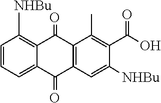 | 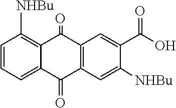 |
| LogP | 4.065 | 3.6 | 3.128 | 2.686 |
| Solubility | 0 mg/mL | 0 mg/mL | 0 mg/mL | 0 mg/mL |
| at pH = 4 | | | | |
| Compound | 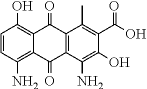 [SMILES: Cc1c(C(=O)O)c(O)c(N)c2c1C(=O)c1c(O)ccc(N)c1C2=O] | 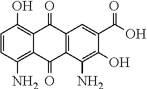 [SMILES: Nc1ccc(O)c2c1C(=O)c1c(cc(C(=O)O)c(O)c1N)C2=O] | 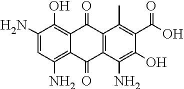 [SMILES: Cc1c(C(=O)O)c(O)c(N)c2c1C(=O)c1c(O)c(N)cc(N)c1C2=O] | 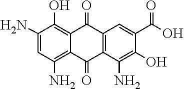 [SMILES: Nc1cc(N)c2c(c1O)C(=O)c1cc(C(=O)O)c(O)c(N)c1C2=O] |
| LogP | −0.04 | −0.494 | −0.823 | −1.314 |
| Solubility | 0.406 mg/mL | 1.257 mg/mL | 0.398 mg/mL | 1.245 mg/mL |
| at pH = 4 | | | | |

Results of Table 1 demonstrate that the compounds of the invention have a higher partition coefficient of about 0.5 log (for experimental and calculated values) than the corresponding non-methylated compounds. These results also demonstrate that the compounds of the invention have a solubility in water three times lower than the corresponding non-methylated compounds.

Thus, compounds of the invention have a better affinity for fibers in comparison to water than the corresponding non-methylated compounds, thereby limiting the possible contamination of waste water by dyestuffs.

### Chemicalize Validation

In order to validate a prediction model, the experimental and theoretical log P of five anthraquinones were assessed. Theoretical values were determined using Chemicalize's online software from ChemAxon, and experimental values were determined by UV-Vis spectroscopy assay using the protocol below. Results are described in Table 2.

A 1:1 mixture of octanol and water (pH=7) was prepared 24 hours before the assay in a reparatory funnel. A precise amount of the product was then added, and sonicated until complete dissolution. The phases were then vigorously stirred and left for 6 hours. The two phases were then separated, the organic phase diluted and analysed by UV spectrophotometry using a calibration curve previously carried out. The aqueous phase was acidified and evaporated. The residue was dissolved in octanol for analysis in UV-Vis spectrophotometry with the same method.

TABLE 2

| Structure | 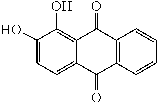 [SMILES: O=C1c2ccccc2C(=O)c2c1ccc(O)c2O] | 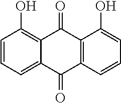 [SMILES: O=C1c2cccc(O)c2C(=O)c2c(O)cccc21] | 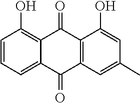 [SMILES: Cc1cc(O)c2c(c1)C(=O)c1cccc(O)c1C2=O] | 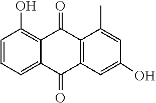 [SMILES: Cc1cc(O)cc2c1C(=O)c1c(O)cccc1C2=O] | 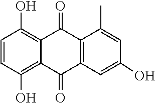 [SMILES: Cc1cc(O)cc2c1C(=O)c1c(O)ccc(O)c1C2=O] |
|---|---|---|---|---|---|
| Name | Alizarin | 1,8-dihydroxy | Chrysophanic | Aloesaponarin | Quinizarin |
| | | anthraquinone | acid | II | |
| Measured | 2.8 | 3.4 | 4.0 | 3.2 | 3.7 |
| logP | | | | | |
| Calculated | 2.9 | 3.6 | 4.1 | 3.4 | 3.6 |
| logP | | | | | |

Measured and calculated log P in Table 2 appears similar for the five molecules, which support the validity of the prediction using Chemicalize.

1-16. (canceled)

17. A compound or a salt thereof having the following formula (I-0): 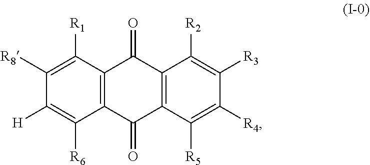
wherein:
R₁, R₄, R₅, R₆ and R₈′ represent independently:
a hydrogen atom,
a group of the following formula (II): 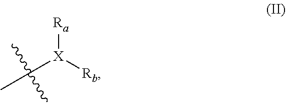
in which:
X is a heteroatom selected from the group consisting of N and P, and
Rₐ and R_{b} represent independently a radical selected from the group consisting of:
a hydrogen atom,
(C₁-C₁₂)alkyl, a (C₂-C₁₂)alkenyl, a (C₂-C₁₂)alkynyl,
an aralkyl or a 3-14 membered ring selected from the group consisting of a cycloalkyl, an aryl, a heterocycloalkyl and a heteroaryl, said aralkyl and said 3-14 membered ring are optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium,
—SO₂—R₈, with R₈ being an aralkyl or a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl, and
—(CO)—R₉, with R₉ being a radical selected from the group consisting of a (C₁-C₁₂)alkyl, a (C₂-C₁₂)alkenyl, a (C₂-C₁₂)alkynyl, an aralkyl, and a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl,
a group of formula (II′) 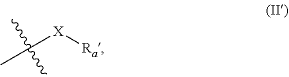
in which:
X is a heteroatom selected from the group consisting of 0, S and Se,
Rₐ′ represents a radical selected from the group consisting of:
a hydrogen atom,
a (C₁-C₁₂)alkyl, a (C₂-C₁₂)alkenyl, a (C₂-C₁₂)alkynyl,
an aralkyl or a 3-14 membered ring selected from the group consisting of a cycloalkyl, an aryl, a heterocycloalkyl, and a heteroaryl, said aralkyl and said 3-14 membered ring are optionally substituted by at least one radical selected from the group consisting of a halogen atom, —NH(CO)R₇ with R₇ being a (C₁-C₁₂)alkyl, —NO₂, —SO₃H, —CO₂H, —CN, a (C₁-C₆)alkyl optionally substituted by one halogen atom, and a tri((C₁-C₆)alkyl)ammonium,
—SO₂—R₈ when X is O, with R₈ being an aralkyl or a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl, and
—(CO)—R₉, with R₉ being a radical selected from the group consisting of a (C₁-C₁₂)alkyl, a (C₂-C₁₂)alkenyl, a (C₂-C₁₂)alkynyl, an aralkyl and a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl; or
a radical selected from the group consisting of:
—NO₂,
—SO₃⁻M⁺ with M⁺ being an alkali metal cation, and
—SO₃R₁₀ and —SO₂NR₁₁R₁₂ with R₁₀, R₁₁, R₁₂ being independently a hydrogen atom or a (C₁-C₆)alkyl;
R₂ represents:
a (C₂-C₂₀)alkyl,
a (C₂-C₂₀)alkenyl, or
a (C₂-C₂₀)alkynyl,
R₃ represents:
a hydrogen atom, or
a radical selected from the group consisting of —C(O)OR₁₃, —C(O)NR₁₄R₁₅, —C(O)SR₁₆, and —C(S)OR₁₇, with R₁₃, R₁₄, R₁₅, R₁₆ and R₁₇ being independently a hydrogen atom, a (C₁-C₁₂)alkyl, a (C₂-C₁₂)alkenyl, a (C₂-C₁₂)alkynyl, a (C₃-C₁₂)cycloalkyl, an aryl or an aralkyl;
with the proviso that at least two of R₁, R₄, R₅, R₆ and R₈′ are not a hydrogen atom, and with the proviso that said compound is not
3,8-dihydroxy-1-methyl-anthracene-9,10-dione,
8-hydroxy-3-methoxy-1-methyl-anthracene-9,10-dione, and
3,8-dihydroxy-1-methyl-9,10-dioxo-anthracene-2-carboxylic acid.

18. The compound according to claim 17, wherein said compound has the following formula (I): 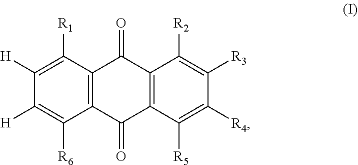
wherein:
R₄, R₅ and R₆ represent independently:
a hydrogen atom,
a group of the following formula (II): 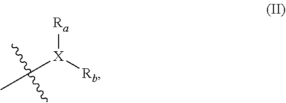
in which:
X is a heteroatom selected from the group consisting of N and P, and
Rₐ and R_{b} represent independently a radical selected from the group consisting of:
a hydrogen atom,
a (C₁-C₁₂)alkyl, a (C₂-C₁₂)alkenyl, a (C₂-C₁₂)alkynyl,
an aralkyl or a 3-14 membered ring selected from the group consisting of a cycloalkyl, an aryl, a heterocycloalkyl and a heteroaryl, said aralkyl and said 3-14 membered ring are optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by one halogen atom, and a tri((C₁-C₆)alkyl)ammonium,
—SO₂—R₈, with R₈ being an aralkyl or a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl, and
—(CO)—R₉, with R₉ being a radical selected from the group consisting of a (C₁-C₁₂)alkyl, a (C₂-C₁₂)alkenyl, a (C₂-C₁₂)alkynyl, an aralkyl, and a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl,
a group of formula (II′) 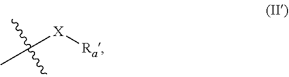
in which:
X is a heteroatom selected from the group consisting of 0, S and Se,
Rₐ′ represents a radical selected from the group consisting of:
a hydrogen atom,
a (C₁-C₁₂)alkyl, a (C₂-C₁₂)alkenyl, a (C₂-C₁₂)alkynyl,
an aralkyl or a 3-14 membered ring selected from the group consisting of a cycloalkyl, an aryl, a heterocycloalkyl, and a heteroaryl, said aralkyl and said 3-14 membered ring are optionally substituted by at least one radical selected from the group consisting of a halogen atom, —NH(CO)R₇ with R₇ being a (C₁-C₁₂)alkyl, —NO₂, —SO₃H, —CO₂H, —CN, a (C₁-C₆)alkyl optionally substituted by one halogen atom, and a tri((C₁-C₆)alkyl)ammonium,
—SO₂—R₈ when X is O, with R₈ being an aralkyl or a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl, and
—(CO)—R₉, with R₉ being a radical selected from the group consisting of a (C₁-C₁₂)alkyl, a (C₂-C₁₂)alkenyl, a (C₂-C₁₂)alkynyl, an aralkyl and a 3-14 membered ring selected from the group consisting of a cycloalkyl, an aryl, a heterocycloalkyl, and a heteroaryl, said aralkyl and said 3-14 membered ring are optionally substituted by at least one (C₁-C₆)alkyl; or
a radical selected from the group consisting of:
—SO₃⁻M⁺ with M⁺ being an alkali metal cation, and
—SO₃R₁₀ and —SO₂NR₁₁R₁₂ with R₁₀, R₁₁, R₁₂ being independently a hydrogen atom or a (C₁-C₆)alkyl;
R₂ represents:
a (C₁-C₂₀)alkyl,
a (C₂-C₂₀)alkenyl, or
a (C₂-C₂₀)alkynyl,
R₃ represents:
a hydrogen atom, or
a radical selected from the group consisting of —C(O)OR₁₃, —C(O)NR₁₄R₁₅, —C(O)SR₁₆, and —C(S)OR₁₇, with R₁₃, R₁₄, R₁₅, R₁₆ and R₁₇ being independently a hydrogen atom, a (C₁-C₁₂)alkyl, a (C₂-C₁₂)alkenyl, a (C₂-C₁₂)alkynyl, a (C₃-C₁₂)cycloalkyl, an aryl or an aralkyl;
with the proviso that at least two of R₁, R₄, R₅ and R₆ are not a hydrogen atom, and
with the proviso that said compound is not
3,8-dihydroxy-1-methyl-anthracene-9,10-dione,
8-hydroxy-3-methoxy-1-methyl-anthracene-9,10-dione, and
3,8-dihydroxy-1-methyl-9,10-dioxo-anthracene-2-carboxylic acid.

19. The compound according to claim 17, wherein R₁ represents a group of formula (II), in which:
X is N, and
Rₐ and R_{b} represent independently a hydrogen atom, a (C₁-C₆)alkyl, a cyclohexyl or a phenyl optionally substituted by at least one radical selected from the group consisting of a halogen atom, —NH(CO)R₇ with R₇ being a (C₁-C₆)alkyl, —NO₂, —SO₃H, —CO₂H, —CN, a (C₁-C₆)alkyl optionally substituted by at least one halogen atom, and a tri((C₁-C₆)alkyl)ammonium.

20. The compound according to claim 17, wherein R₁ represents a group of formula (II′), in which:
—X is O, and
Rₐ′ represents a radical selected from the group consisting of a hydrogen atom and —SO₂—R₈, with R₈ being a phenyl substituted by a (C₁-C₆)alkyl.

21. The compound according to claim 17, wherein R₄ represents a group of formula (II), in which:
X is N, and
Rₐ and R_{b} represent independently a hydrogen atom, a (C₁-C₆) alkyl, a cyclohexyl group or a phenyl group optionally substituted by at least one radical selected from the group consisting of a halogen atom, a (C₁-C₆)alkyl optionally substituted by at least one halogen atom, —NH(CO)R₇ with R₇ being a (C₁-C₆)alkyl, —NO₂, —SO₃H, —CO₂H and a tri(C₁-C₆ alkyl)ammonium.

22. The compound according to claim 17, wherein R₅ and R₆ represent independently a hydrogen atom or —NH₂.

23. The compound according to claim 17, wherein R₂ is a (C₁-C₆)alkyl, a (C₁-C₂)alkyl, or a methyl group.

24. The compound according to claim 17, wherein R₃ is a hydrogen atom or —C(O)OR₁₃ with R₁₃ being a hydrogen atom or (C₁-C₆)alkyl.

25. The compound according to claim 17, wherein:
R₁ represents —OH, —O—SO₂-Tol, —NH—C₆H₅, —NH-Cy, —NHBu, or —NH—C₆H₄—NHCO—CH₃,
R₄ represents —NH—C₆H₅, —NH-Cy, —NHBu, or —NH—C₆H₄—NHCO—CH₃,
R₅ and R₆ represent independently a hydrogen atom or —NH₂,
R₃ represents a hydrogen atom or —COOH, and
R₂ is a methyl.

26. The compound according to claim 17, wherein said compound is selected from the group consisting of:
3-amino-8-hydroxy-1-methyl-anthracene-9,10-dione,
3-anilino-8-hydroxy-1-methyl-anthracene-9,10-dione,
(6-anilino-8-methyl-9,10-dioxo-1-anthryl)-4-methylbenzenesulfonate,
3,8-dianilino-1-methyl-anthracene-9,10-dione,
N-(3-((6-(3-acetamidoanilino)-8-methyl-9,10-dioxo-1-anthryl)amino)phenyl)acetamide,
3,8-bis(cyclohexylamino)-1-methyl-anthracene-9,10-dione,
3,8-bis(cyclohexylamino)-1-methyl-9,10-dioxo-9,10-dihydroanthracene-2-carboxylic acid;
3,8-bis(butylamino)-1-methyl-9,10-dioxo-9,10-dihydroanthracene-2-carboxylic acid;
1-amino-2,5-dihydroxy-4-methyl-anthracene-9,10-dione;
1,8-diamino-2,5-dihydroxy-4-methyl-anthracene-9,10-dione;
4,5-diamino-3,8-dihydroxy-1-methyl-9,10-dioxo-anthracene-2-carboxylic acid; and
4,5,7-triamino-3,8-dihydroxy-1-methyl-9,10-dioxo-anthracene-2-carboxylic acid.

27. A method for colouring a substrate or a surface comprising contacting said substrate or said surface with a compound according to claim 17.

28. The method according to claim 27, wherein the substrate or surface is selected from plastics, waxes, cellulosic materials, silicones, textiles, leathers, food, pharmaceutical compositions, skin, hair, stone, glass, paper, silicone, wood or metal.

29. A colouring composition comprising from 0.01% to 20% by weight of a compound according to claim 17.

30. The colouring composition according to claim 29, which is a dyestuff for colouring textiles or leathers.

31. The colouring composition according to claim 29, further comprising a solvent and optionally (i) one or more additives facilitating the colouration of the textile or skin; and/or (ii) one or more additional colouring agents.

32. The colouring composition according to claim 31, wherein the additive is selected from the group consisting of antifoaming agents, anticreasing agents, wetting agents, dispersants, lubricants, detergents, inorganic salts, reducing agents, oxidising agents, carriers which cause polyester fibers to swell during dyeing and thus allow the colourants to penetrate, and antioxidants.

33. The colouring composition according to claim 29, wherein the colouring composition is an ink or a colouring composition for colouring plastics, waxes, cellulosic materials, silicones, textiles, leathers, food compositions, cosmetic compositions, or pharmaceutical compositions.

34. An organic electroluminescent device or a solar cell comprising a compound according to claim 17.
